(19) United States
(12) Patent Application Publication
(10) Pub. No.: US 2026/0362034 A1
(43) Pub. Date: Nov. 12, 2026

(54) LIGHT SENSING DEVICE

(71) Applicant: SONY SEMICONDUCTOR SOLUTIONS CORPORATION, Kanagawa (JP)

(72) Inventors: Hajime YAMAGISHI, Kanagawa (JP); Yoshiki EBIKO, Kanagawa (JP); Ryoichi NAKAMURA, Kanagawa (JP); Hidenobu TSUGAWA, Kanagawa (JP)

(73) Assignee: SONY SEMICONDUCTOR SOLUTIONS CORPORATION, Kanagawa (JP)

(21) Appl. No.: 19/135,243

(22) PCT Filed: Dec. 6, 2023
(86) PCT No.: PCT/JP2023/043729

§ 371 Date: Jun. 3, 2025

(30) Foreign Application Priority Data
Dec. 15, 2022 (JP) 2022-200023

(51) Int. Cl. H04N 25/773; H04N 25/79; H10F 39/00

(52) U.S. Cl. CPC H04N 25/773; H04N 25/79; H10F 39/8057; H10F 39/8063; H10F 39/811

(57) ABSTRACT

Disclosed herein is a light detecting device including a first substrate section, a second substrate section, and first light shielding walls disposed in the first substrate section and the second substrate section. The first substrate include a first semiconductor substrate and a plurality of photodiodes in the first semiconductor substrate. The second substrate section is stacked on the first substrate section and includes a second semiconductor substrate and a plurality of avalanche photodiodes in the second semiconductor substrate. A part of the first light shielding walls surround a region in a cross-sectional view, the region disposed above the first avalanche photodiode of the plurality of avalanche photodiodes in a light-receiving direction.

### CROSS REFERENCE TO RELATED APPLICATIONS

This application claims the benefit of Japanese Priority Patent Application JP 2022-200023 filed Dec. 15, 2022, the entire contents of which are incorporated herein by reference.

### TECHNICAL FIELD

The present disclosure relates to a light sensing device.

### BACKGROUND ART

Typically, in a case where three-dimensional data is to be added to an image captured with an image sensor by synthesizing information regarding the image and information regarding a distance measured with a distance sensor, respective chips of the image sensor and the distance sensor are created and arranged in separate camera modules, and data processing in a downstream circuit establishes consistency between the image information and the distance information. In this case, a plurality of the camera modules is necessary, and the cost increases. In addition, the footprint of the modules also increases, and further, since optical axes of the respective modules are different from each other, the parallax increases in a case of short distances, and data processing taking into consideration the parallax becomes necessary.

In order to solve this, a multilayered sensor in which a logic circuit and a chip including arrayed SPAD (single photon avalanche diode) pixels are stacked one on another has been proposed (see PTL 1, for example).

### CITATION LIST

### Patent Literature

PTL 1: JP 2019-47486A

### SUMMARY

### Technical Problem

By stacking a substrate (hereinafter, a visible light pixel array) on which visible light pixels are arranged in an array on the light incidence surface side of a substrate (hereinafter, an SPAD pixel array) on which SPAD pixels (or avalanche photodiodes) are arranged in an array, it is possible to make the optical axes of distance measurement and imaging coincide (or almost coincide) with each other. However, since light transmitted through the visible light pixel array enters the SPAD pixel array in this multilayered light sensing device, there has been a problem that color mixing or attenuation of light that enters the SPAD pixels tends to occur, and sensing characteristics of the SPAD pixels tend to deteriorate.

The present disclosure has been made in view of such circumstances, and it is desirable to provide a multilayered light sensing device that can suppress deterioration of characteristics.

### Solution to Problem

According to an embodiment of the present disclosure, there is provided a light detecting device comprising: a first substrate section including: a first semiconductor substrate; and a plurality of photodiodes in the first semiconductor substrate; a second substrate section stacked on the first substrate section including: a second semiconductor substrate; and a plurality of avalanche photodiodes in the second semiconductor substrate; and first light shielding walls disposed in the first substrate section and the second substrate section, wherein a part of the first light shielding walls surround a region in a cross-sectional view, the region disposed above the first avalanche photodiode of the plurality of avalanche photodiodes in a light-receiving direction.

According to an aspect of the present disclosure, there is provided a light detecting device in which the second substrate section further includes a separation region disposed in the second semiconductor substrate, wherein the separation region separates a first avalanche photodiode from a second avalanche photodiode adjacent to the first avalanche photodiode, and the first light shielding walls are disposed above the separation region in a light-receiving direction.

According to an aspect of the present disclosure, there is provided a light detecting device in which each of the plurality of the first light shielding walls surrounding the region is connected to another of the plurality of the first light shielding walls.

According to an aspect of the present disclosure, there is provided a light detecting device in which the first light shielding walls have first parts disposed in the first substrate section and second parts of the first light shielding walls disposed in the second substrate section.

According to an aspect of the present disclosure, there is provided a light detecting device in which the first substrate section further includes a first wiring layer disposed on a surface side of the first semiconductor substrate, wherein the first wiring layer faces the second semiconductor substrate, the second substrate section further includes a second wiring layer disposed on a surface side of the second semiconductor substrate, wherein the second wiring layer faces the first semiconductor substrate, the first wiring layer comprises a first interlayer dielectric film and first wires, the second wiring layer comprises a second interlayer dielectric film and second wires, the first parts of the first light shielding walls include the first wires, and the second parts of the first light shielding walls include the second wires.

According to an aspect of the present disclosure, there is provided a light detecting device in which the first wiring layer comprises first connection pads including one or more of copper (Cu) and a Cu alloy, the second wiring layer comprises second connection pads including one or more of Cu and a Cu alloy, the first connection pads and the second connection pads are bonded together at a bonding portion between the first substrate section and the second substrate section, the first parts of the first light shielding walls include the first connection pads, and the second parts of the first light shielding walls include the second connection pads.

According to an aspect of the present disclosure, there is provided a light detecting device in which the first connection pads included in the first parts of the first light shielding walls and the second connection pads included in the second parts of the first light shielding walls are arranged between the first semiconductor substrate and the second semiconductor substrate.

According to an aspect of the present disclosure, there is provided a light detecting device in which the region is a waveguide region, and the first avalanche photodiode is not arranged in the waveguide region.

According to an aspect of the present disclosure, there is provided a light detecting device in which the first substrate section comprises the waveguide region.

According to an aspect of the present disclosure, there is provided a light detecting device further comprising a second light shielding wall between the first light shielding walls and the waveguide region.

According to an aspect of the present disclosure, there is provided a light detecting device further comprising a second waveguide in the second substrate section.

According to an aspect of the present disclosure, there is provided a light detecting device in which the waveguide region is surrounded by the first light shielding walls in the cross-sectional view.

According to an aspect of the present disclosure, there is provided a light detecting device in which a through hole penetrates the first substrate section in the waveguide region.

According to an aspect of the present disclosure, there is provided a light detecting device in which wherein the waveguide region comprises silicon oxide (SiO).

According to an aspect of the present disclosure, there is provided a light detecting device in which the light detecting device further includes a third substrate section, and the third substrate section includes: a third semiconductor substrate, and processing circuitry provided in the third semiconductor substrate.

According to an aspect of the present disclosure, there is provided a light detecting device in which the processing circuitry includes at least either of avalanche photodiode circuits connected to the avalanche photodiodes and imaging pixel circuits connected to the photodiodes.

According to an aspect of the present disclosure, there is provided a light detecting device in which further comprising lens bodies arranged opposite the second substrate section with the first substrate section being interposed therebetween, wherein the lens bodies include: first lenses that condense light onto the photodiodes, and second lenses that condense light onto the avalanche photodiodes, and wherein the first lenses and the second lenses have mutually different curvatures.

According to an aspect of the present disclosure, there is provided a light detecting device in which the avalanche photodiodes are single photon avalanche diode pixels.

According to an embodiment of the present disclosure, there is provided a light detecting apparatus comprising: a plurality of lenses; a first substrate section including: a first semiconductor substrate; and a plurality of photodiodes in the first semiconductor substrate; a second substrate section stacked on the first substrate section including: a second semiconductor substrate; and a plurality of avalanche photodiodes in the second semiconductor substrate; and first light shielding walls disposed in the first substrate section and the second substrate section, wherein a plurality of the first light shielding walls surround a waveguide region in a cross-sectional view.

According to an aspect of the present disclosure, there is provided a light detecting apparatus in which the second substrate section further includes a separation region disposed in the second semiconductor substrate, wherein the separation region separates a first avalanche photodiode from a second avalanche photodiode adjacent to the first avalanche photodiode, and the first light shielding walls are disposed above the separation region in a light-receiving direction.

A light sensing device according to a mode of the present disclosure includes a light sensing device including a multilayered substrate having a first substrate section and a second substrate section bonded to one surface of the first substrate section. The first substrate section has a first semiconductor substrate, and a plurality of imaging pixels provided in the first semiconductor substrate. The second substrate section has a second semiconductor substrate that faces the first semiconductor substrate, and a plurality of distance measurement pixels provided in the second semiconductor substrate. The multilayered substrate further has first light shading walls that are provided between the first semiconductor substrate and the second semiconductor substrate and surround individual ones of the distance measurement pixels in a plan view as seen in a thickness direction of the multilayered substrate.

Thus, an optical path for each distance measurement pixel from the light exit surface of the first semiconductor substrate to the distance measurement pixel is surrounded by a first light shading wall. Thus, diffusion of light to the outside of the path can be suppressed, and color mixing between distance measurement pixels can be suppressed. Even in a case where the first substrate section is stacked on the light incidence surface side of the second substrate section having the distance measurement pixels, light can be caused to enter the distance measurement pixels efficiently. Thus, deterioration of characteristics of the distance measurement pixels (e.g., conversion efficiency (QE)) can be suppressed.

A light sensing device according to another mode of the present disclosure includes a light sensing device including a multilayered substrate having a first substrate section and a second substrate section bonded to one surface of the first substrate section. The first substrate section has a first semiconductor substrate, and a plurality of imaging pixels provided in the first semiconductor substrate. The second substrate section has a second semiconductor substrate that faces the first semiconductor substrate, and a plurality of distance measurement pixels provided in the second semiconductor substrate. The first semiconductor substrate has waveguide regions that are at positions overlapping the distance measurement pixels in a thickness direction of the multilayered substrate and are for introducing light having entered the other surface opposite the one surface of the first substrate section to the distance measurement pixels in the second substrate section. The imaging pixels are not arranged in the waveguide regions. The multilayered substrate has waveguides that are provided between the waveguide regions in the first semiconductor substrate and the distance measurement pixels in the second semiconductor substrate and are for introducing the light from the waveguide regions to the distance measurement pixels.

Thus, since the imaging pixels are not provided on optical paths from the other surface of the first semiconductor substrate to the distance measurement pixels, it becomes easier to arrange wires or the like connected to the imaging pixels at positions away from the optical paths. It is possible to prevent light heading to the distance measurement pixels from being attenuated or reflected by hitting the imaging pixels or the wires or the like connected to the imaging pixels. Thus, for example, deterioration of the conversion efficiency (QE) can be suppressed further.

### BRIEF DESCRIPTION OF DRAWINGS

FIG. 1 is a block diagram depicting a configuration example of a light sensing device according to a first embodiment of the present disclosure.

FIG. 2 is a block diagram depicting a configuration example of an imaging section according to the first embodiment of the present disclosure.

FIG. 3 is a block diagram depicting a configuration example of a distance measuring section according to the first embodiment of the present disclosure.

FIG. 4A is a plan view depicting a configuration example of a first substrate section according to the first embodiment of the present disclosure.

FIG. 4B is a plan view depicting a configuration example of a second substrate section according to the first embodiment of the present disclosure.

FIG. 4C is a plan view depicting a configuration example of a third substrate section according to the first embodiment of the present disclosure.

FIG. 5 is a diagram depicting a configuration example of SPAD circuits.

FIG. 6 is a flowchart depicting an operation example of each of SPAD circuits and CIS circuits in the light sensing device.

FIG. 7 is a cross-sectional view depicting a configuration example of the light sensing device according to the first embodiment of the present disclosure.

FIG. 8 is a diagram depicting an enlarged view of a part of the cross-section depicted in FIG. 7.

FIG. 9 is a cross-sectional view depicting a configuration example of SPAD pixels according to the first embodiment of the present disclosure.

FIG. 10 is a plan view illustrating a positional relation between a first light shading wall and a second light shading wall, and a waveguide region in the light sensing device according to the first embodiment of the present disclosure.

FIG. 11 is a plan view depicting a size example (first modification example) of waveguide regions of the light sensing device according to the first embodiment of the present disclosure.

FIG. 12 is a plan view depicting a size example (second modification example) of the waveguide regions of the light sensing device according to the first embodiment of the present disclosure.

FIG. 13 is a plan view depicting a size example (third modification example) of the waveguide regions of the light sensing device according to the first embodiment of the present disclosure.

FIG. 14 is a plan view depicting a size example (fourth modification example) of the waveguide regions of the light sensing device according to the first embodiment of the present disclosure.

FIG. 15 is a cross-sectional view depicting a configuration example of a light sensing device according to a second embodiment of the present disclosure.

FIG. 16 is a cross-sectional view depicting a configuration example of a light sensing device according to a third embodiment of the present disclosure.

FIG. 17 is a step diagram depicting a method of forming bonding pads and light shading sidewalls which is a part of steps to manufacture the light sensing device according to the third embodiment of the present disclosure.

FIG. 18 is a plan view illustrating a positional relation between first connection pads and second connection pads, and waveguide regions and CIS pixels in the light sensing device according to the third embodiment of the present disclosure.

FIG. 19 is a cross-sectional view depicting a configuration example of a light sensing device according to a fourth embodiment of the present disclosure.

FIG. 20 is a cross-sectional view depicting a configuration example of a light sensing device according to a fifth embodiment of the present disclosure.

FIG. 21 is a plan view illustrating a positional relation between first light shading walls and CIS pixels in the light sensing device according to the fifth embodiment of the present disclosure.

FIG. 22 is a block diagram depicting an example of schematic configuration of a vehicle control system.

FIG. 23 is a diagram of assistance in explaining an example of installation positions of an outside-vehicle information detecting section and an imaging section.

### DESCRIPTION OF EMBODIMENTS

Hereinbelow, embodiments of the present disclosure are explained with reference to the figures. In the descriptions of the figures that are referred to in the following explanation, identical or similar portions are given identical or similar reference signs. It should be noted, however, that the figures are schematic figures, and the relations between thicknesses and plane dimensions, the rates of the thicknesses of respective layers, and the like are different from actual ones. Accordingly, specific thicknesses and dimensions should be determined by taking the following explanation into consideration. In addition, certainly, dimensions in different figures may have different relations and rates.

Definitions of directions such as the up-down direction in the following explanation are definitions that are used simply for convenience of explanation, and do not limit the technical idea of the present disclosure. For example, certainly, if a target object is observed after being rotated 90°, the up-down direction mentioned in an explanation of the target object is interpreted as meaning the left-right direction, and if the target object is observed after being rotated 180°, the up-down direction mentioned in the explanation is interpreted as meaning an inverted direction.

In some cases, in the following explanation, directions are explained by use of phrases X-axis direction, Y-axis direction and Z-axis direction. Both the X-axis direction and the Y-axis direction are directions parallel to a rear surface 5b (light incidence surface) of a first semiconductor substrate 5. The X-axis direction and the Y-axis direction may be referred to as horizontal directions. The Z-axis direction is a direction that perpendicularly intersects the rear surface 5b (light incidence surface) of the first semiconductor substrate 5, and also is a thickness direction of a multilayered substrate 200. The Z-axis direction is an example of a “thickness direction of a multilayered substrate” of an embodiment of the present disclosure. The X-axis direction, the Y-axis direction, and the Z-axis direction are orthogonal to each other.

### First Embodiment

### Configuration Example of Light Sensing Device

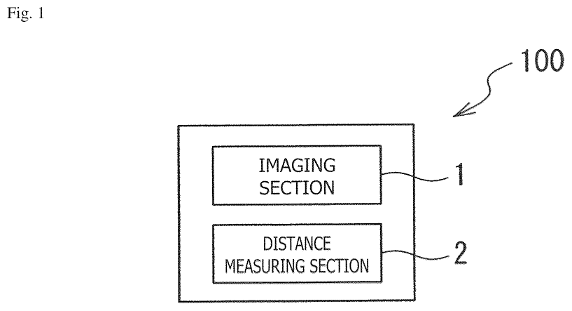

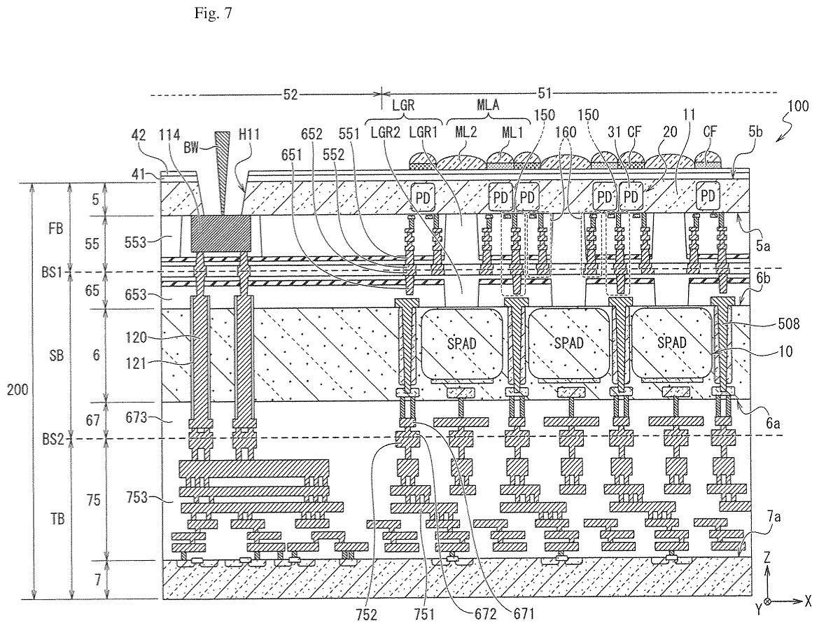

FIG. 1 is a block diagram depicting a configuration example of a light sensing device 100 according to a first embodiment of the present disclosure. As depicted in FIG. 1, the light sensing device 100 according to the first embodiment of the present disclosure includes an imaging section 1 and a distance measuring section 2. The light sensing device 100 is a light sensing device with a multilayered layer structure including a first substrate section FB (see FIG. 7 mentioned later) and a second substrate section SB (see FIG. 7 mentioned later) bonded on one surface side of the first substrate section FB. A plurality of CIS pixels 20 (CIS: CMOS Image Sensors; an example of “imaging pixels” of an embodiment of the present disclosure) of the imaging section 1 is provided in the first substrate section FB, and a plurality of SPAD pixels 10 (an example of “distance measurement pixels” of an embodiment of the present disclosure) of the distance measuring section 2 is provided in the second substrate section SB. In addition, the light sensing device 100 further includes a third substrate section TB (see FIG. 7 mentioned later) arranged opposite the first substrate section FB with the second substrate section SB being interposed therebetween. First, a configuration example of each of the imaging section 1 and the distance measuring section 2 is explained.

### Configuration Example of Imaging Section

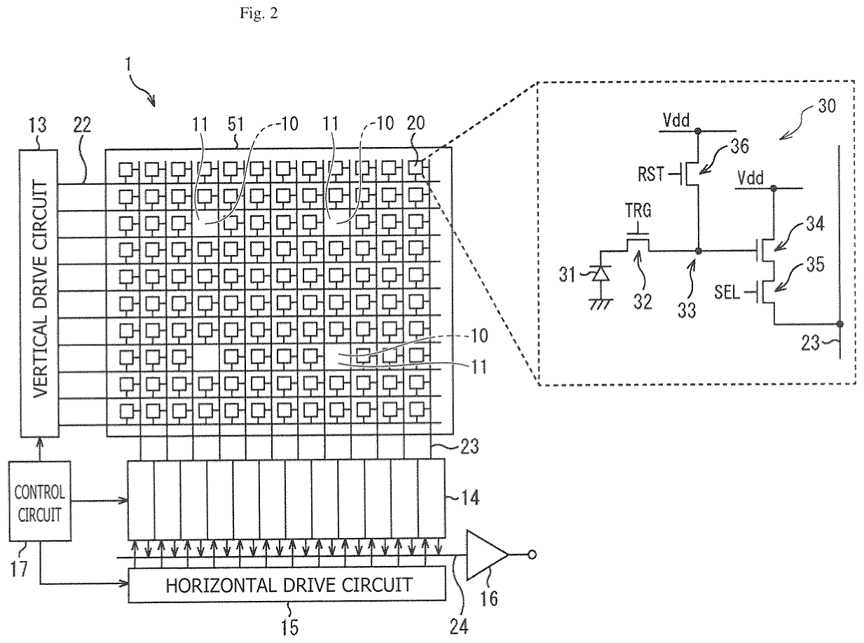

FIG. 2 is a block diagram depicting a configuration example of the imaging section 1 according to the first embodiment of the present disclosure. As depicted in FIG. 2, the imaging section 1 includes the plurality of CIS pixels 20 provided in a pixel region 51, a vertical drive circuit 13, column signal processing circuits 14, a horizontal drive circuit 15, an output circuit 16, and a control circuit 17. For example, the CIS pixels 20 sense visible light.

The CIS pixels 20 are light reception regions that receive visible light condensed by optical systems not depicted. The plurality of CIS pixels 20 are arranged in an array (e.g., a plurality of CIS pixels 20 are arrayed in each of the X-axis direction and the Y-axis direction). The plurality of CIS pixels 20 are connected to the vertical drive circuit 13 in units of rows via horizontal signal lines 22 and also is connected to the column signal processing circuits 14 in units of columns via vertical signal lines 23. Each of the plurality of CIS pixels 20 outputs a pixel signal at a level according to the light amount of received visible light. From those pixel signals, an image of a subject is constructed.

The vertical drive circuit 13 supplies, to the CIS pixels 20 via the horizontal signal lines 22, drive signals for sequentially driving (transferring, selecting, resetting, etc.) the respective CIS pixels 20 in units of rows of the plurality of CIS pixels 20. The column signal processing circuits 14 perform AD conversion on pixel signals output from the plurality of CIS pixels 20 via the vertical signal lines 23 and also remove reset noises by implementing a CDS (Correlated Double Sampling) process on the pixel signals.

The horizontal drive circuit 15 supplies, to the column signal processing circuits 14, drive signals for sequentially causing the column signal processing circuits 14 to output pixel signals to a data output signal line 24 in units of columns of the plurality of CIS pixels 20. The output circuit 16 amplifies the pixel signals supplied from the column signal processing circuits 14 via the data output signal line 24 at timings according to the drive signals of the horizontal drive circuit 15 and outputs the pixel signals to a downstream signal processing circuit. The control circuit 17 controls driving of each block inside the imaging section 1. For example, the control circuit 17 generates a clock signal according to the drive cycle of each block and supplies the clock signals to the respective blocks.

Each CIS pixel 20 includes a PN photodiode 31 that performs photoelectric conversion on visible light, a transfer transistor 32, a floating diffusion 33, an amplification transistor 34, a selection transistor 35, and a reset transistor 36. The transfer transistor 32, the floating diffusion 33, the amplification transistor 34, the selection transistor 35, and the reset transistor 36 are included in a readout circuit 30 that reads out charge (pixel signal) having been subjected to photoelectric conversion at the PN photodiode 31.

The PN photodiode 31 is a photoelectric converting section that converts incident visible light into charge by photoelectric conversion, and the charge is accumulated therein. The PN photodiode 31 has an anode terminal connected to the ground and also a cathode terminal connected to the transfer transistor 32. The transfer transistor 32 is driven according to a transfer signal (TRG) supplied from the vertical drive circuit 13, and when the transfer transistor 32 is turned on, the charge accumulated in the PN photodiode 31 is transferred to the floating diffusion 33. The floating diffusion 33 is a floating diffusion region that is connected to the gate electrode of the amplification transistor 34 and that has predetermined accumulation capacitance, and the charge transferred from the PN photodiode 31 is temporarily accumulated in the floating diffusion 33.

The amplification transistor 34 outputs a pixel signal at a level according to the charge accumulated in the floating diffusion 33 (i.e., the potential of the floating diffusion 33) to the vertical signal line 23 via the selection transistor 35. That is, with the configuration in which the floating diffusion 33 is connected to the gate electrode of the amplification transistor 34, the floating diffusion 33 and the amplification transistor 34 function as a converting section that amplifies charge generated at the PN photodiode 31 and converts the charge into a pixel signal at a level according to the charge.

The selection transistor 35 is driven according to a selection signal SEL supplied from the vertical drive circuit 13, and when the selection transistor 35 is turned on, it becomes possible for the pixel signal output from the amplification transistor 34 to be output to the vertical signal line 23. The reset transistor 36 is driven according to a reset signal RST supplied from the vertical drive circuit 13, and when the reset transistor 36 is turned on, the charge accumulated in the floating diffusion 33 is discharged to a drain power supply (Vdd), and the floating diffusion 33 is reset.

In the pixel region 51 depicted in FIG. 2, regions represented by blanks are mixedly present in the array of the arrayed CIS pixels 20. For example, the SPAD pixels 10 are arranged below those regions represented by the blanks. These blank regions are regions for introducing light to the SPAD pixels 10, and the CIS pixels 20 are not arranged therein. Hereinbelow, these blank regions are also referred to as waveguide regions.

### Configuration Example of Distance Measuring Section

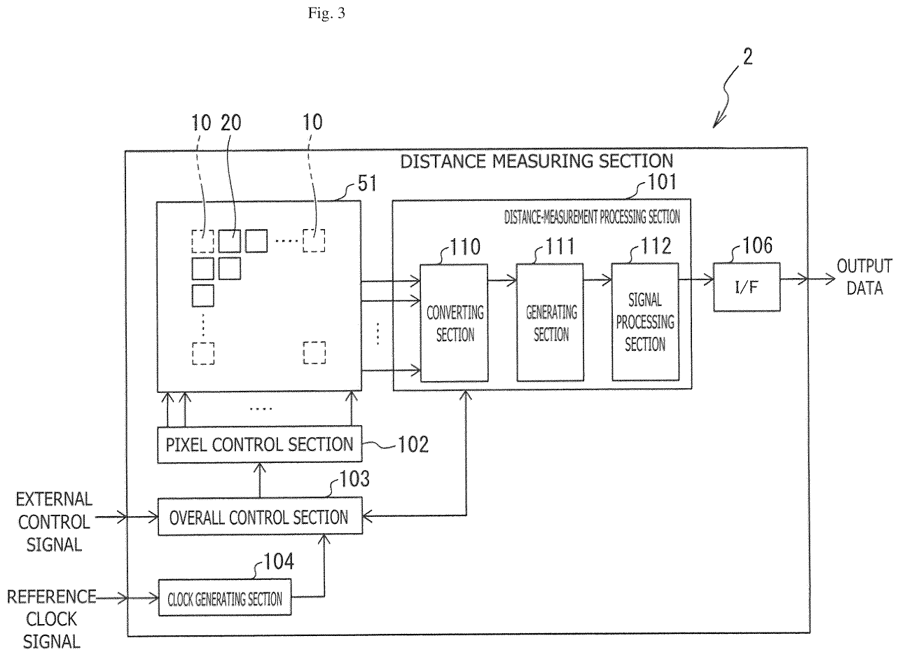

FIG. 3 is a block diagram depicting a configuration example of the distance measuring section 2 according to the first embodiment of the present disclosure. For example, the distance measuring section 2 is a device that performs distance measurement by direct time of flight (ToF) and computes a distance from the length of time that it takes for illumination light emitted from an external light source (not depicted) to be reflected and return. As depicted in FIG. 3, the distance measuring section 2 includes one or more SPAD pixels 10 arranged in the pixel region 51, a distance-measurement processing section 101, a pixel control section 102, an overall control section 103, a clock generating section 104, and an interface (I/F) 106. The SPAD pixels 10 sense infrared rays as monitoring light, for example. The SPAD pixels 10, the distance-measurement processing section 101, the pixel control section 102, the overall control section 103, the clock generating section 104, and the I/F 106 are arranged in the second substrate section SB or the third substrate section TB (see FIG. 7 mentioned later) of the multilayered substrate 200.

In FIG. 3, the overall control section 103 controls overall operation of the distance measuring section 2 according to a pre-incorporated program, for example. In addition, the overall control section 103 can also execute control according to external control signals supplied from the outside. The clock generating section 104 generates one or more clock signals to be used in the distance measuring section 2, on the basis of reference clock signals supplied from the outside.

Operation of the SPAD pixels 10 is controlled by the pixel control section 102 according to instructions from the overall control section 103. For example, the pixel control section 102 can also control the SPAD pixels 10 singly or in units of blocks each including a plurality of SPAD pixels 10.

A pixel signal read out from each SPAD pixel 10 is supplied to the distance-measurement processing section 101. The distance-measurement processing section 101 includes a converting section 110, a generating section 111, and a signal processing section 112.

A pixel signal read out from each SPAD pixel 10 is supplied to the converting section 110. Here, pixel signals are read out from the SPAD pixels 10 asynchronously, and supplied to the converting section 110. That is, the pixel signals are read out and output from the SPAD pixels 10 according to timings at which light is received at the SPAD pixels 10.

The converting section 110 converts a pixel signal output from each SPAD pixel 10 into digital information. That is, a pixel signal output from each SPAD pixel 10 is output corresponding to a timing at which the SPAD pixel 10 to which the pixel signal corresponds has received light. The converting section 110 converts the pixel signal output from the SPAD pixel 10 into time information representing the timing.

The generating section 111 generates a histogram on the basis of time information generated by the converting section 110 converting pixel signals. The signal processing section 112 performs a predetermined calculation process on the basis of data of the histogram generated by the generating section 111 and computes distance information, for example. For example, the signal processing section 112 creates a fitting curve of the histogram on the basis of the data of the histogram generated by the generating section 111. The signal processing section 112 can sense a peak of the fitting curve of the histogram and determine a distance on the basis of the sensed peak.

The signal processing section 112 can implement a filtering process on the fitting curve of the histogram when performing the curve fitting of the histogram. For example, the signal processing section 112 can suppress noise components by implementing a low pass filtering process on the fitting curve of the histogram.

The distance information determined at the signal processing section 112 is supplied to the interface 106. The interface 106 outputs, to the outside and as output data, the distance information supplied from the signal processing section 112. For example, a mobile industry processor interface (MIPI) can be applied as the interface 106.

Note that, whereas the distance information determined at the signal processing section 112 is output to the outside via the interface 106 in the exampled mentioned above, this is not the sole example. That is, in other possible configuration, histogram data which is the data of the histogram generated by the generating section 111 is output from the interface 106 to the outside. For example, the histogram data output from the interface 106 is supplied to and processed at an external information processing device as appropriate.

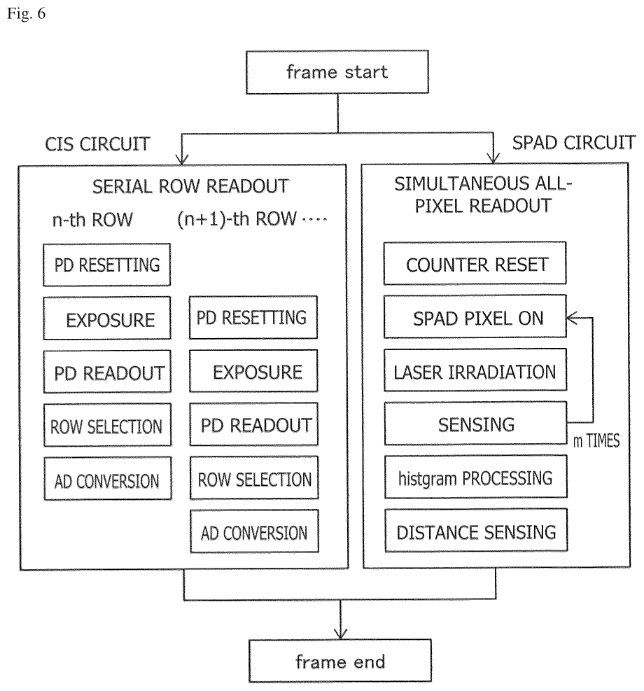

Note that at least some of the functions of the distance-measurement processing section 101 depicted in FIG. 3 are executed by SPAD circuits 210 mentioned later. The relation between each of the functions of the distance-measurement processing section 101 and the SPAD circuits 210 is explained with reference to FIG. 5 later. Next, a configuration example of each of the first substrate section FB, the second substrate section SB, and the third substrate section TB is explained.

### Configuration Example of First Substrate Section

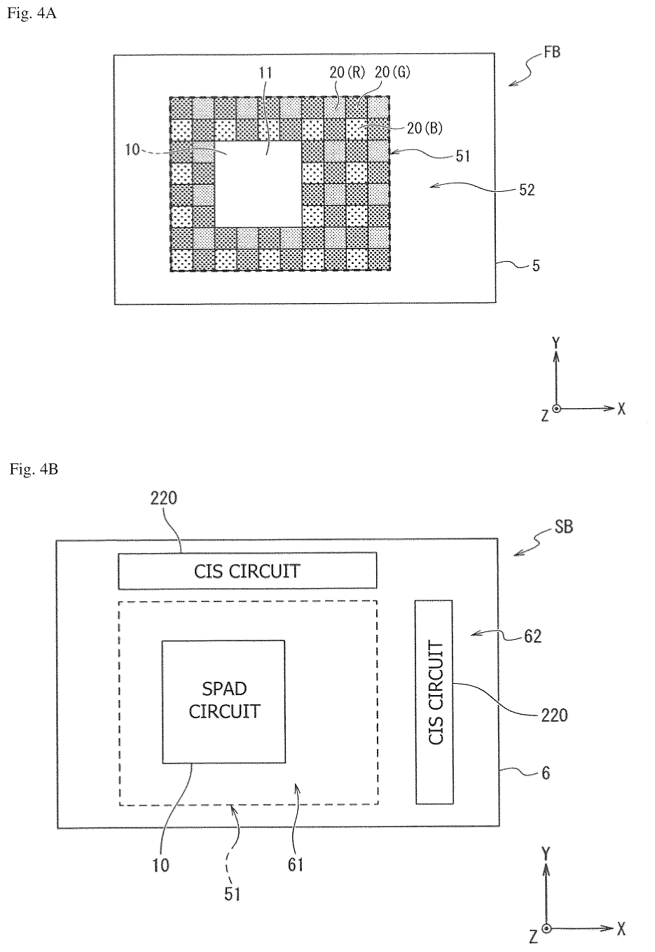

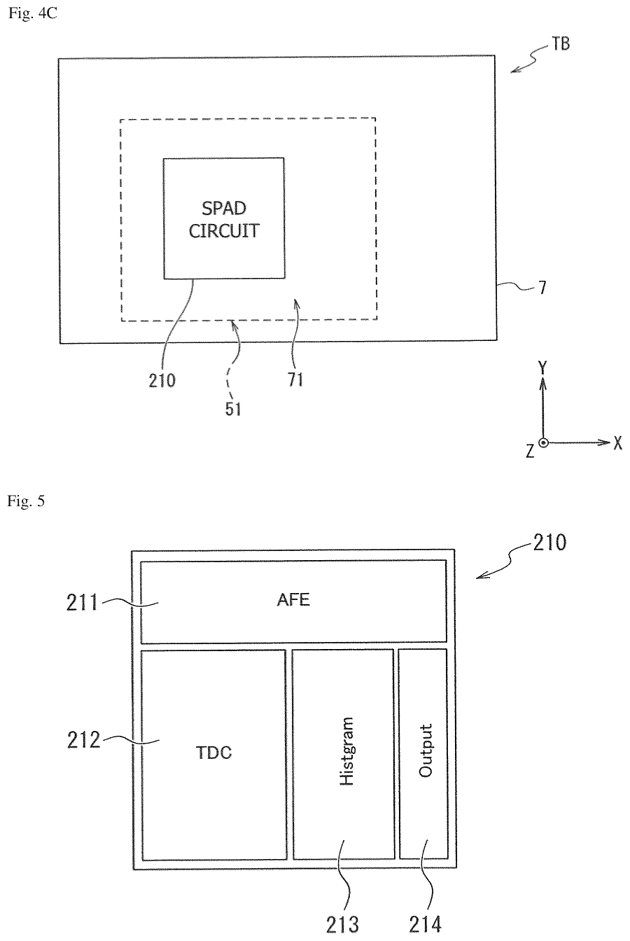

FIG. 4A is a plan view depicting a configuration example of the first substrate section FB according to the first embodiment of the present disclosure. As depicted in FIG. 4A, the first substrate section FB has the first semiconductor substrate 5, the plurality of CIS pixels 20 provided in the first semiconductor substrate 5, and a plurality of waveguide regions 11 provided in the first semiconductor substrate. As mentioned above, the waveguide regions 11 are regions for introducing light to the SPAD pixels 10, and the CIS pixels 20 are not arranged therein.

Whereas FIG. 4A depicts only one waveguide region 11, the plurality of waveguide regions 11 are provided in an array at constant intervals in the first semiconductor substrate 5. Each of the plurality of waveguide regions 11 is surrounded by CIS pixels 20 in a plan view as seen in a thickness direction (e.g., the Z-axis direction) of the first semiconductor substrate 5. One waveguide region 11 is adjacent to a plurality of CIS pixels 20.

In the pixel region 51, the plurality of waveguide regions 11 and the plurality of CIS pixels 20 are arranged mixedly in an array. Waveguide regions 11 and CIS pixels 20 are not arranged in a peripheral region 52 positioned around the pixel region 51.

Note that, whereas FIG. 4A depicts the peripheral region 52 as a relatively large area as compared to the pixel region 51, this is merely an example. The peripheral region 52 may be sufficiently small in the first substrate section FB relative to the pixel region 51.

In addition, whereas FIG. 4A depicts a case where the size, in a plan view, of an SPAD pixel 10 positioned below the waveguide region 11 (i.e., the pixel area size of the SPAD pixel 10) is sixteen times greater than the pixel area size of a CIS pixel 20 (a length which is four times greater in the X-axis direction, and a length which is four times greater in the Y-axis direction), this is merely an example. For example, as depicted in FIG. 10 mentioned later, the pixel area size of an SPAD pixel 10 may be four times greater than the pixel area size of a CIS pixel 20 (a length which is twice greater in the X-axis direction, and a length which is twice greater in the Y-axis direction).

### Configuration Example of Second Substrate Section

FIG. 4B is a plan view depicting a configuration example of the second substrate section SB according to the first embodiment of the present disclosure. As depicted in FIG. 4B, the second substrate section SB has a second semiconductor substrate 6, the plurality of SPAD pixels 10 provided in the second semiconductor substrate 6, and a first circuit region 61 and a second circuit region 62 provided in the second semiconductor substrate 6. The SPAD pixels 10 are arranged at positions overlapping the waveguide regions 11 depicted in FIG. 4A in the thickness direction (e.g., the Z-axis direction) of the multilayered substrate 200 depicted in FIG. 7 mentioned later. For example, the SPAD pixels 10 are arranged immediately below the waveguide regions 11. Note that, whereas FIG. 4B depicts only one SPAD pixel 10, the plurality of SPAD pixels 10 are provided in an array at constant intervals in the second semiconductor substrate 6.

For example, the first circuit region 61 is provided at a position overlapping, in the Z-axis direction, the pixel region 51 depicted in FIG. 4A excluding the waveguide region 11. In addition, a part of the first circuit region 61 may be arranged at a position overlapping the peripheral region 52 in the Z-axis direction. The readout circuits 30 (see FIG. 2), each of which is connected to one of the multiple CIS pixels 20, are arranged in the first circuit region 61.

For example, the second circuit region 62 is provided at a position overlapping, in the Z-axis direction, the peripheral region 52 depicted in FIG. 4A. CIS circuits 220 (an example of an “imaging pixel circuit” of an embodiment of the present disclosure) connected to the plurality of CIS pixels 20 are arranged in the second circuit region 62. Each CIS circuit 220 includes the vertical drive circuit 13, the column signal processing circuits 14, the horizontal drive circuit 15, the output circuit 16, and the control circuit 17 depicted in FIG. 2.

### Configuration Example of Third Substrate Section

FIG. 4C is a plan view depicting a configuration example of the third substrate section TB according to the first embodiment of the present disclosure. As depicted in FIG. 4C, a third circuit region 71 is provided in a third semiconductor substrate 7 of the third substrate section TB. For example, the third circuit region 71 is provided at a position overlapping, in the Z-axis direction, the pixel region 51 depicted in FIG. 4A. The SPAD circuits 210 (an example of an “electronic circuit” and a “distance-measurement pixel circuit” of an embodiment of the present disclosure) connected to the SPAD pixels 10 provided in the second substrate section SB are provided in the third circuit region 71. For example, corresponding to the plurality of SPAD pixels 10 depicted in FIG. 4B, a plurality of the SPAD circuits 210 are arranged in the third circuit region 71 in the third semiconductor substrate 7. Immediately below one SPAD pixel 10, one SPAD circuit 210 corresponding to the one SPAD pixel 10 is arranged.

Note that circuits arranged in the third circuit region 71 are not limited to the SPAD circuits 210. For example, at least either of the SPAD circuits 210 and the CIS circuits 220 may be arranged in the third circuit region 71. Some of the CIS circuits 220 may be arranged in the third circuit region 71 in addition to the SPAD circuits 210, or any logic circuit or any analog circuit may be arranged in the third circuit region 71. In addition, in the third semiconductor substrate 7, some of the CIS circuits 220 may be arranged also in a region that is positioned around the third circuit region 71 or any logic circuit or any analog circuit may be arranged in the region.

### Configuration Example of SPAD Circuits

FIG. 5 is a diagram depicting a configuration example of SPAD circuits 210. As depicted in FIG. 5, each SPAD circuit 210 has an analog front end (AFE) circuit 211, a time to digital converter (TDC) circuit 212, a Histogram circuit 213, and an output section 214. Thus, the SPAD circuit 210 executes at least some of the functions of the distance-measurement processing section 101.

For example, as a part of the functions of the converting section 110 of the distance-measurement processing section 101 depicted in FIG. 3, the AFE circuit 211 converts a pixel signal output from each SPAD pixel 10 into digital information.

As another part of the functions of the converting section 110, the TDC circuit 212 converts digital information output from the AFE circuit 211 into time information. As the respective functions of the generating section 111 and signal processing section 112 of the distance-measurement processing section 101 depicted in FIG. 3, the Histogram circuit 213 generates a histogram on the basis of the time information output from the TDC circuit 212 and computes distance information by performing a predetermined calculation process on the basis of data of the generated histogram. As a function of the interface 106, the Output section 214 outputs the computed distance information to the outside as output data.

### Operation Examples of Circuits

FIG. 6 is a flowchart depicting an operation example of each of the SPAD circuits 210 and the CIS circuits 220 in the light sensing device 100. As depicted in FIG. 6, while reading out signals for one screen (i.e., from a frame start to a frame end), a CIS circuit 220 performs serial row readout operation, and in parallel with this, an SPAD circuit 210 performs all-pixel simultaneous readout operation.

For example, while reading out signals for one screen, the CIS circuit 220 sequentially performs photodiode (PD) resetting, exposure, PD readout, row selection, and analog to digital (AD) conversion in order of the n-th row (n is an integer equal to or greater than one), the (n+1)-th row, and the (n+2)-th row . . . . The CIS circuit 220 performs PD resetting of the (n+1)-th row at a timing at which exposure of the n-th row is performed. In addition, while reading out signals for one screen, the SPAD circuit 210 performs counter resetting, SPAD pixel (SPAD element) ON, laser irradiation, sensing, histogram processing, and distance sensing. The process from the SPAD pixel ON to the sensing is performed m times (m is an integer equal to or greater than one) as necessary.

### Example of Cross-Sectional Structure

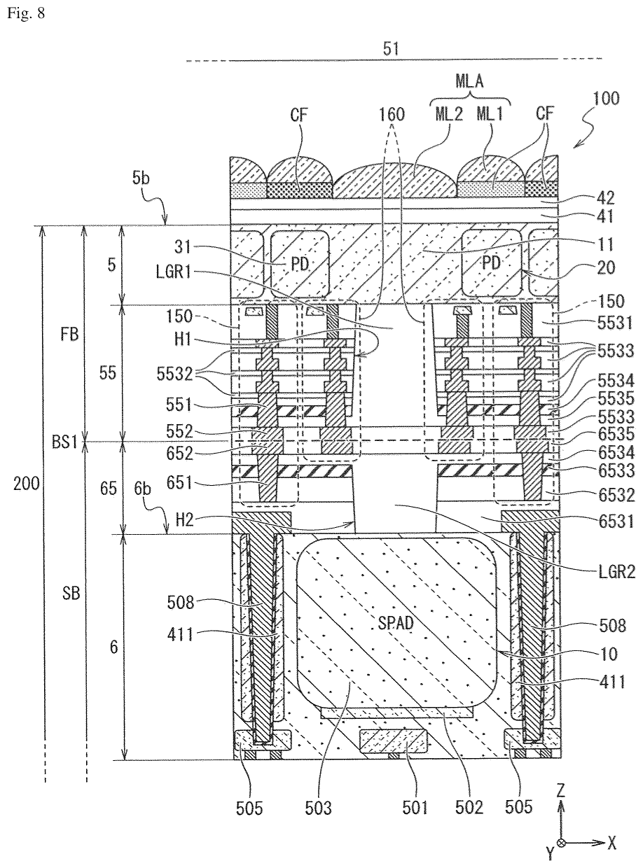

FIG. 7 is a cross-sectional view depicting a configuration example of the light sensing device 100 according to the first embodiment of the present disclosure. FIG. 8 is a diagram depicting an enlarged view of a part of the cross-section depicted in FIG. 7. As depicted in FIG. 7, the light sensing device 100 includes the multilayered substrate 200, color filters CF, and microlens arrays MLA (“lens bodies” of an embodiment of the present disclosure). The multilayered substrate 200 has the first substrate section FB, the second substrate section SB bonded to the one surface side of the first substrate section FB, and the third substrate section TB bonded to a surface of the second substrate section SB opposite to the surface to which the first substrate section FB is bonded.

For example, the light sensing device 100 is a backside illumination optical sensor, and the rear surface 5b side (the upper surface side in FIG. 7) of the first semiconductor substrate 5 in the first substrate section FB is the light incidence surface side. Because of this, the color filters CF and the microlens arrays MLA are arranged on the rear surface 5b side of the first semiconductor substrate 5.

The first substrate section FB has the first semiconductor substrate 5 and a first wiring layer 55 provided on a front surface 5a side (a lower surface side in FIG. 7; an example of a “surface side that faces the second semiconductor substrate” of an embodiment of the present disclosure) of the first semiconductor substrate 5.

For example, the first semiconductor substrate 5 is a silicon substrate formed by polishing a silicon wafer by CMP (Chemical Mechanical Polishing). The plurality of CIS pixels 20 are provided in the first semiconductor substrate 5.

A light-transmitting dielectric film 41 is provided on the rear surface 5b of the first semiconductor substrate 5, and a light-transmitting dielectric film 42 is provided on the dielectric film 41. For example, the dielectric film 41 includes a material having a refractive index higher than that of the refractive index of the dielectric film 42. For example, the dielectric film 41 includes a silicon nitride (SiN) film, and the dielectric film 42 includes a silicon oxide (SiO) film. The dielectric films 41 and 42 can protect the rear surface 5b of the first semiconductor substrate 5. In addition, the difference between the refractive indices of the dielectric films 41 and 42 allows suppression of reflection of light that enters the rear surface 5b side of the first semiconductor substrate 5.

The color filters CF and the microlens arrays MLA are stacked one on another in this order on the rear surface 5b of the first semiconductor substrate 5 via the dielectric films 41 and 42. For example, the microlens arrays MLA are arranged in the pixel region 51, but not arranged in the peripheral region 52. Each of the microlens arrays MLA has a microlens ML1 (an example of a “first lens” of an embodiment of the present disclosure) arranged above a CIS pixel 20, and a microlens ML2 (an example of a “second lens” of an embodiment of the present disclosure) arranged above an SPAD pixel 10.

The microlens ML1 condenses incident light that enters the first substrate section FB onto the CIS pixel 20 in the first substrate section FB. The microlens ML2 condenses incident light that enters the first substrate section FB onto the SPAD pixel 10 in the second substrate section SB. The microlenses ML1 and ML2 have mutually different curvatures.

End portions of adjacent microlenses ML1 and ML2 or end portions of one microlens ML2 and another microlens ML2 that are adjacent to each other are connected together to form one microlens array MLA.

The color filters CF are arranged above the CIS pixels 20, but not arranged above the SPAD pixels 10. The microlenses ML1 are arranged on the color filters CF. The microlenses ML2 are arranged on the light-transmitting dielectric film 42 with color filters CF not being interposed therebetween. Thus, light transmitted through the microlenses ML1 passes through the color filters CF to enter the CIS pixels 20. Light transmitted through the microlenses ML2 enters the SPAD pixels 10 without passing through the color filters CF.

Note that, although not depicted in FIG. 7 and FIG. 8, element separating sections with trench structures may be provided in the first semiconductor substrate 5. One CIS pixel 20 and another CIS pixel 20 that are adjacent to each other among the plurality of CIS pixels 20 may be separated by such an element separating section. In addition, a waveguide region 11 provided in the first semiconductor substrate 5 and a CIS pixel 20 adjacent to the waveguide region 11 may be separated by such an element separating section.

The first wiring layer 55 has first wires 551 connected to the CIS pixels 20, first connection pads 552, and a first interlayer dielectric film 553 that covers the first wires 551.

For example, the first wires 551 are multilayer wires formed over a plurality of layers. For example, the first interlayer dielectric film 553 is a multilayered film formed through film formation steps that are performed multiple times. The first wires 551 include metal such as aluminum (Al) or an Al alloy or copper (Cu) or a Cu alloy. In addition, at least parts of the first wires 551 may include a high-melting-point metal such as tungsten (W) or a conductive material such as polysilicon doped with impurities.

For example, the first connection pads 552 are connected to the first wires 551 and include Cu or a Cu alloy. The front surfaces (lower surfaces in FIG. 7 and FIG. 8) of the first connection pads 552 are exposed through the front surface (lower surface in FIG. 7 and FIG. 8) of the first interlayer dielectric film 553.

For example, the first interlayer dielectric film 553 is a multilayered film formed through film formation steps that are performed multiple times and includes a multilayer dielectric film such as an SiO film, an SiN film, a silicon carbide (SiC) film, a TEOS film, or an HDP film. For example, as depicted in FIG. 8, the first interlayer dielectric film 553 has a structure in which an SiO film 5531, SiC films 5532 and TEOS films 5533 that are stacked alternately on the SiO film 5531, an SiN film 5534, an HDP film 5535 and a TEOS film 5536 are stacked in this order from the front surface 5a of the first semiconductor substrate 5 to the front surface side (the lower surface side in FIG. 7 and FIG. 8) of the first interlayer dielectric film 553.

TEOS films are oxide films formed by using tetra ethoxy silane (Si(OC₂H₅)₄) as a raw material. The TEOS films 5533 and 5536 are both oxide films formed by using Si(OC₂H₅)₄.

HDP films are dielectric films formed by an HDP-CVD (high-density plasma CVD) method. CVD stands for chemical vapor deposition (Chemical Vapor Deposition). For example, the HDP film 5535 is an SiO film formed by an HDP-CVD method.

The SiC film 5532 in each of the layers has a function to suppress diffusion of Cu included in the first wires 551 in the Z-axis direction (i.e., inter-layer diffusion).

In addition, as depicted in FIG. 7 and FIG. 8, the first interlayer dielectric film 553 is provided with openings H1 from the front surface of the first interlayer dielectric film 553 to the front surface 5a side of the first semiconductor substrate 5. The openings H1 are through holes penetrating the first interlayer dielectric film 553 in the thickness direction (e.g., the Z-axis direction). In this case, at the bottom planes of the openings H1, there is the front surface 5a of the first semiconductor substrate 5. Alternatively, the openings H1 may not be penetrating through holes. In this case, at the bottom planes of the openings H1, there may be parts (e.g., the SiO film 5531) of the first interlayer dielectric film 553 that are left unremoved.

The openings H1 are provided immediately below the waveguide regions 11 and filled with the HDP film 5535. The HDP film 5535 filling the openings H1 functions as first waveguides LGR1 which are parts of waveguides LGR. The first waveguides LGR1 may be in a first substrate section (FB) while second waveguide regions LGR2 may be in a second substrate section (SB).

As depicted in FIG. 7 and FIG. 8, the second substrate section SB has the second semiconductor substrate 6, a second wiring layer 65 provided on a rear surface 6b side (an example of a “surface side that faces the first semiconductor substrate” of an embodiment of the present disclosure) of the second semiconductor substrate 6, and a third wiring layer 67 provided on a front surface 6a side of the second semiconductor substrate 6.

For example, the second semiconductor substrate 6 is a silicon substrate formed by polishing a silicon wafer by CMP. The second semiconductor substrate 6 is provided with the SPAD pixels 10 and the CIS circuits 220 (see FIG. 4B). A configuration example of the SPAD pixels 10 is explained later.

The second wiring layer 65 has second wires 651, second connection pads 652, and a second interlayer dielectric film 653 that covers the second wires 651. The second wires 651 may be monolayer wires or may be multilayer wires formed over a plurality of layers. For example, the second interlayer dielectric film 653 is a multilayered film formed through film formation steps that are performed multiple times. The second wires 651 include metal such as aluminum (Al) or an Al alloy or copper (Cu) or a Cu alloy. In addition, at least parts of the second wires 651 may include high-melting-point metal such as tungsten (W) or a conductive material such as polysilicon doped with impurities.

For example, the second connection pads 652 are connected to the second wires 651 and include Cu or a Cu alloy. The front surfaces (upper surfaces in FIG. 7 and FIG. 8) of the second connection pads 652 are exposed through the front surface (upper surface in FIG. 7 and FIG. 8) of the second interlayer dielectric film 653.

For example, the second interlayer dielectric film 653 is a multilayered film formed through film formation steps that are performed multiple times and includes a multilayer dielectric film such as an SiO film, an SiN film, a TEOS film, or an HDP film. For example, as depicted in FIG. 8, the second interlayer dielectric film 653 has a structure in which an SiO film 6531, a TEOS film 6532, an SiN film 6533, an HDP film 6534, and a TEOS film 6535 are stacked in this order from the rear surface 6b of the second semiconductor substrate 6 to the front surface side (the upper surface side in FIG. 7 and FIG. 8) of the second interlayer dielectric film 653.

The second interlayer dielectric film 653 is provided with openings H2 from the front surface of the second interlayer dielectric film 653 to the rear surface 6b side of the second semiconductor substrate 6. The openings H2 are through holes penetrating the second interlayer dielectric film 653 in the thickness direction (e.g., the Z-axis direction). In this case, at the bottom planes of the openings H2, there is the rear surface 6b of the second semiconductor substrate 6. Alternatively, the openings H2 may not be penetrating through holes. In this case, at the bottom planes of the openings H2, there may be parts (e.g., the SiO film 6531) of the second interlayer dielectric film 653 that are left unremoved.

The openings H2 are provided immediately below the waveguide regions 11 and filled with the HDP film 6534. The HDP film 6534 filling the openings H2 functions as second waveguides LGR2 which are parts of waveguides LGR.

As depicted in FIG. 7, the third wiring layer 67 has third wires 671, third connection pads 672, and a third interlayer dielectric film 673 that covers the third wires 671. The third wires 671 may be monolayer wires or may be multilayer wires formed over a plurality of layers. For example, the third interlayer dielectric film 673 is a multilayered film formed through film formation steps that are performed multiple times. The third wires 671 include metal such as aluminum (Al) or an Al alloy or copper (Cu) or a Cu alloy. In addition, at least parts of the third wires 671 may include high-melting-point metal such as tungsten (W) or a conductive material such as polysilicon doped with impurities.

For example, the third connection pads 672 are connected to the third wires 671 and include Cu or a Cu alloy. The front surfaces (lower surfaces in FIG. 7) of the third connection pads 672 are exposed through the front surface (lower surface in FIG. 7) of the third interlayer dielectric film 673. For example, the third interlayer dielectric film 673 includes a multilayer dielectric film such as an SiO film or a TEOS film.

As mentioned above, the second substrate section SB is bonded to the one surface side (lower surface side in FIG. 7 and FIG. 8) of the first substrate section FB. For example, the first wiring layer 55 of the first substrate section FB and the second wiring layer 65 of the second substrate section SB are bonded together. More specifically, the first interlayer dielectric film 553 and the second interlayer dielectric film 653 are bonded together at a bonding surface BS1 between the first wiring layer 55 and the second wiring layer 65. In addition, the first connection pads 552 and the second connection pads 652 are bonded together at the bonding surface BS1. The first connection pads 552 and the second connection pads 652 both include Cu or a Cu alloy and are Cu-Cu-bonded together. Thus, the second substrate section SB is bonded to the one surface side of the first substrate section FB. In addition, the first wires 551 are connected to the second wires 651 via the first connection pads 552 and the second connection pads 652.

In addition, the first waveguides LGR1 and the second waveguides LGR2 are bonded together to form the waveguides LGR that introduce light from the waveguide regions 11 in the first semiconductor substrate 5 to the SPAD pixels 10 in the second semiconductor substrate 6. For example, the first waveguides LGR1 and the second waveguides LGR2 are bonded together via the TEOS films 5533 and 6535 to form the waveguides LGR. The first waveguides LGR1 penetrate the SiN film 5534, and the second waveguides LGR2 penetrate the SiN film 6533.

For example, the waveguides LGR include only SiO. In the waveguides LGR, there is not a SiN film whose refractive index is significantly different from the refractive index of SiO (e.g., an HDP film or a TEOS film). Thus, the waveguides LGR can introduce light from the waveguide regions 11 to the SPAD pixels 10 efficiently (i.e., with suppressed attenuation or reflection of the light).

As depicted in FIG. 7, the third substrate section TB has the third semiconductor substrate 7 and a fourth wiring layer 75 provided on a front surface 7a side of the third semiconductor substrate 7.

For example, the third semiconductor substrate 7 is a silicon substrate formed by polishing a silicon wafer by CMP. The third semiconductor substrate 7 is provided with the SPAD circuits 210 (see FIG. 4C). In addition, the third semiconductor substrate 7 may be provided with at least some of the CIS circuits 220 (see FIG. 4C).

The fourth wiring layer 75 has fourth wires 751, fourth connection pads 752, and a fourth interlayer dielectric film 753 that covers the fourth wires 751. The fourth wires 751 may be monolayer wires or may be multilayer wires formed over a plurality of layers. For example, the fourth interlayer dielectric film 753 is a multilayered film formed through film formation steps that are performed multiple times. The fourth wires 751 include metal such as aluminum (Al) or an Al alloy or copper (Cu) or a Cu alloy. In addition, at least parts of the fourth wires 751 may include high-melting-point metal such as tungsten (W) or a conductive material such as polysilicon doped with impurities.

For example, the fourth connection pads 752 are connected to the fourth wires 751 and include Cu or a Cu alloy. The front surfaces (upper surfaces in FIG. 7) of the fourth connection pads 752 are exposed through the front surface (upper surface in FIG. 7) of the fourth interlayer dielectric film 753. For example, the fourth interlayer dielectric film 753 is a multilayered film formed through film formation steps that are performed multiple times and includes a multilayer dielectric film such as an SiO film or a TEOS film.

The third substrate section TB is bonded to one surface side (lower surface side in FIG. 7 and FIG. 8) of the second substrate section SB. For example, the third wiring layer 67 of the second substrate section SB and the fourth wiring layer 75 of the third substrate section TB are bonded together. More specifically, the third interlayer dielectric film 673 and the fourth interlayer dielectric film 753 are bonded together at a bonding surface BS2 between the third wiring layer 67 and the fourth wiring layer 75. In addition, the third connection pads 672 and the fourth connection pads 752 are bonded together at the bonding surface BS2. The third connection pads 672 and the fourth connection pads 752 both include Cu or a Cu alloy and are Cu-Cu-bonded together. Thus, the third substrate section TB is bonded to the one surface of the second substrate section SB. In addition, the third wires 671 are connected to the fourth wires 751 via the third connection pads 672 and the fourth connection pads 752.

As depicted in FIG. 7, a bonding pad 114 is arranged in the peripheral region 52. Whereas FIG. 7 depicts one bonding pad 114, a plurality of bonding pads 114 are provided in the peripheral region 52. For example, each of the plurality of bonding pads 114 is arrayed along one of four sides on a two-dimensional plane of a semiconductor chip (i.e., the multilayered substrate 200 formed into a single piece by dicing). Each of the plurality of bonding pads 114 is an input/output terminal to be used when the semiconductor chip is electrically connected with an external device.

A pad opening section H11 is provided above the bonding pad 114. The pad opening section H11 penetrates the first semiconductor substrate 5, and there is the bonding pad 114 at the bottom plane of the pad opening section H11. One end of a bonding wire BW including a conductive material such as gold (Au) is bonded to the bonding pad 114 exposed through the pad opening section H11.

For example, among the plurality of bonding pads 114, one bonding pad 114 is connected to the first wires 551 in the first wiring layer 55. In addition, another bonding pad 114 is connected to the second wires 651 in the second wiring layer 65 via the first wiring layer 55. Still another bonding pad 114 is connected to the third wiring layer 67 or the fourth wiring layer 75 via the first wiring layer 55, and the second wiring layer 65, and conductors 120 (e.g., through silicon vias) mentioned later.

The conductors 120 penetrating the second semiconductor substrate 6 in its thickness direction (e.g., the Z-axis direction) are provided below the bonding pads 114. In addition, dielectric films 121 are provided on the side surfaces of through holes of the second semiconductor substrate 6 where the conductors 120 are arranged. The dielectric films 121 insulate the conductors 120 from the second semiconductor substrate 6.

The conductors 120 are electrodes penetrating the second semiconductor substrate 6. Since, for example, the second semiconductor substrate 6 includes silicon in the present embodiment, the conductors 120 are through silicon vias (TSVs, Through-Silicon Vias). Although uses of the conductors 120 are not limited to any kind in the present embodiment, for example, they are used as power lines, reference potential (e.g., ground potential) lines, or signal lines. Accordingly, the conductors 120 preferably include a low-electrical-resistance material. Examples of the low-electrical-resistance material include copper (Cu) or a Cu alloy, for example.

Note that, whereas FIG. 7 depicts a mode in which the conductors 120 (e.g., TSVs) penetrating the second semiconductor substrate 6 are arranged in the peripheral region 52, the arrangement position of the conductors 120 is not limited to the peripheral region 52. The conductors 120 penetrating the second semiconductor substrate 6 may be arranged in the pixel region 51. In addition, the conductors 120 arranged in the peripheral region 52 and the conductors 120 arranged in the pixel region 51 may include a mutually identical material or may include mutually different materials. The conductors 120 arranged in the peripheral region 52 and the conductors 120 arranged in the pixel region 51 may have a mutually identical width or may have mutually different widths. For example, the conductors 120 arranged in the peripheral region 52 may have widths which are greater than the widths of the conductors 120 arranged in the pixel region 51. Thus, the conductors 120 arranged in the peripheral region 52 can have lowered resistance as compared to the resistance of the conductors 120 arranged in the pixel region 51 by an amount corresponding to the difference between the widths.

### Configuration Example of SPAD Pixels

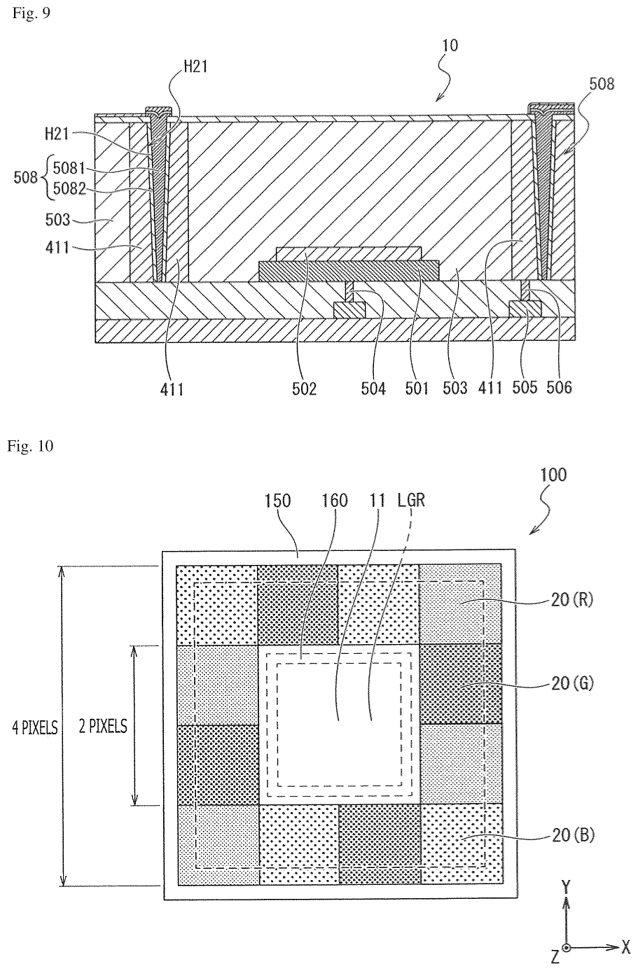

FIG. 9 is a cross-sectional view depicting a configuration example of the SPAD pixels 10 according to the first embodiment of the present disclosure. FIG. 9 is a cross-sectional view depicting a configuration example of the SPAD pixels 10 that can be applied to the direct-ToF distance measuring section 2 according to the first embodiment of the present disclosure.

As depicted in FIG. 9, an SPAD pixel 10 is provided with an N-conductivity-type semiconductor region 501 and a P-type semiconductor region 502 contacting the N-type semiconductor region 501. The N-type semiconductor region 501 and the P-type semiconductor region 502 are provided in a well layer 503.

The well layer 503 may be an N-conductivity-type semiconductor region or may be a P-conductivity-type semiconductor region. In addition, for example, the well layer 503 is preferably an N-type or P-type semiconductor region with a low concentration on the order of 1×10¹⁴/cm³ or lower. Thus, it becomes easier to deplete the well layer 503, and it is possible to attempt to enhance the sense efficiency referred to as PDE (Photon Detection Efficiency).

For example, the N-type semiconductor region 501 is an N-type semiconductor region including Si (silicon) and having a high impurity concentration. The P-type semiconductor region 502 is a P-type semiconductor region having a high impurity concentration. The P-type semiconductor region 502 forms a pn junction at the interface between itself and the N-type semiconductor region 501. The P-type semiconductor region 502 has a multiplication region that avalanche-multiplies a carrier generated by entrance of light to be sensed. The P-type semiconductor region 502 is preferably depleted, and thereby it is possible to attempt to enhance the PDE.

The N-type semiconductor region 501 functions as a cathode and is connected to an SPAD circuit 210 (see FIG. 5, for example) via a contact 504. A hole (hole) accumulation region 411 is a P-type semiconductor region. For example, the hole accumulation region 411 is a region which is substantially identical to an anode 505 and is provided in a state where it is electrically connected with the anode 505 via a contact 506. The anode 505 is connected to the SPAD circuit 210 (see FIG. 5, for example).

A separation region 508 that separates SPAD pixels 10 is formed, and the hole accumulation region 411 is provided between the separation region 508 and the well layer 503. The separation region 508 may separate a first avalanche photodiode from a second avalanche photodiode adjacent to the first avalanche photodiode.

The hole accumulation region 411 is formed at a portion where different materials contact. Since the separation region 508 includes a material which is different from the material of the well layer 503 in the example depicted in FIG. 9, the hole accumulation region 411 is provided in order to suppress dark current that is generated at the interface between the separation region 508 and the well layer 503. The hole accumulation region 411 may further be provided also at the upper portion (the light incidence surface side of the SPAD pixel 10) of the well layer 503.

The separation region 508 is formed between SPAD pixels 10 and separates the SPAD pixels 10. The separation region 508 is formed in a two-dimensional grid such that it completely surrounds the circumference of each multiplication region (SPAD pixel 10).

For example, the separation region 508 has a trench H21, a light-shading film 5081 filling the trench H21, and a dielectric film 5082 interposed between the side surface of the trench H21 and the light-shading film 5081. For example, the light-shading film 5081 includes tungsten (W), Al or an Al alloy, Cu or a Cu alloy, polysilicon, or the like. For example, the dielectric film 5082 includes an SiO film.

Whereas the separation region 508 is provided to penetrate the well layer 503 from its upper surface side to its lower surface side in the thickness direction (e.g., the Z-axis direction) of the multilayered substrate 200 in the mode depicted in the example depicted in FIG. 9, modes of the separation region 508 are not limited to this. For example, the separation region 508 may not penetrate the well layer 503 in the Z-axis direction. The separation region 508 may be provided to an intermediate position of the well layer 503 in the Z-axis direction.

### Configuration Example of Light Shading Walls Surrounding Waveguides

As depicted in FIG. 7 and FIG. 8, the light sensing device 100 has first light shading walls 150 each including a first wire 551, a first connection pad 552, a second connection pad 652, and a second wire 651. Each first light shading wall 150 is provided between the first semiconductor substrate 5 and the second semiconductor substrate 6 and is, for example, arranged at a position overlapping the separation region 508 in the Z-axis direction (i.e., above the separation region 508). The first light shading wall 150 is provided continuously from the first wire 551 to the second wire 651 along the thickness direction (e.g., the Z-axis direction) of the multilayered substrate 200.

For example, the first light shading wall 150 has a first part that is provided to the first substrate section FB and faces the second substrate section SB. The first part includes the first wire 551 and the first connection pad 552. In addition, the first light shading wall 150 has a second part that is provided in the second substrate section SB and faces the first substrate section FB. The second part includes the second wire 651 and the second connection pad 652. The first connection pad 552 and the second connection pad 652 included in the first light shading wall 150 are Cu-Cu-bonded.

Similarly, the light sensing device 100 has second light shading walls 160 each including a first wire 551, a first connection pad 552, and a second connection pad 652. Each second light shading wall 160 is provided between the first semiconductor substrate 5 and the second semiconductor substrate 6, and is, for example, arranged between a second light shading wall 160 and a waveguide LGR. The second light shading wall 160 is provided continuously from the first wire 551 to the second connection pad 652 along the thickness direction (e.g., the Z-axis direction) of the multilayered substrate 200.

For example, the second light shading wall 160 has a third part that is provided to the first substrate section FB and faces the second substrate section SB. The third part includes the first wire 551 and the first connection pad 552. In addition, the second light shading wall 160 has a fourth part that is provided to the second substrate section SB and faces the first substrate section FB. The fourth part includes the second connection pad 652. The first connection pad 552 and the second connection pad 652 included in the second light shading wall 160 are Cu-Cu-bonded together.

FIG. 10 is a plan view illustrating a positional relation between a first light shading wall 150 and a second light shading wall 160, and a waveguide region 11 in the light sensing device 100 according to the first embodiment of the present disclosure. Note that, in FIG. 10, a CIS pixel 20(R) represents a CIS pixel positioned under a red color filter CF (see FIG. 7 and FIG. 8), a CIS pixel 20(G) represents a CIS pixel positioned under a green color filter CF, and a CIS pixel 20(B) represents a CIS pixel positioned under a blue color filter CF.

As depicted in FIG. 10, the first light shading wall 150 is arranged to surround the waveguide region 11 uninterruptedly and continuously in plan view as seen in the thickness (or light-receiving) direction (e.g., the Z-axis direction) of the multilayered substrate 200. Whereas FIG. 10 depicts only one waveguide region 11, the first light shading walls 150 are arranged to surround individual ones of the multiple waveguide regions 11. While in some implementations, the light shading wall 150 may surround the waveguide region 11 uninterruptedly and continuously, in some implementations the waveguide region 11 may be surrounded by multiple disconnected walls.

The second light shading wall 160 is arranged between a first light shading wall 150 and a waveguide LGR. The second light shading wall 160 is arranged to surround the waveguide LGR continuously in plan view as seen in the Z-axis direction. Whereas FIG. 10 depicts only one waveguide region 11, the second light shading walls 160 are arranged to surround individual ones of the multiple waveguide regions 11.

### Advantages of First Embodiment

As explained above, the light sensing device 100 according to the first embodiment of the present disclosure includes the multilayered substrate 200 having the first substrate section FB and the second substrate section SB bonded to one surface of the first substrate section FB. The first substrate section FB has the first semiconductor substrate 5 and the plurality of CIS pixels 20 provided to the first semiconductor substrate 5. The second substrate section SB has the second semiconductor substrate 6 that faces the first semiconductor substrate 5, and the plurality of SPAD pixels 10 provided to the second semiconductor substrate 6. The multilayered substrate 200 further has the first light shading walls 150 that are provided between the first semiconductor substrate 5 and the second semiconductor substrate 6 and surround individual ones of the multiple SPAD pixels 10 in plan view as seen in the thickness direction (e.g., the Z-axis direction) of the multilayered substrate 200.

Thus, since the first substrate section FB having the plurality of CIS pixels 20 and the second substrate section SB having the plurality of SPAD pixels 10 are stacked, it is possible to make the optical axes of imaging and distance measurement coincide (or almost coincide) with each other. Thus, the light sensing device 100 can acquire images for imaging and distance images with identical optical axes.

In addition, an optical path (e.g., a path including a waveguide LGR) for each SPAD pixel 10 from the front surface 5a (light exit surface) of the first semiconductor substrate 5 to the SPAD pixel 10 is surrounded by a first light shading wall 150. Thus, diffusion of light to the outside of the path can be suppressed, and color mixing between the SPAD pixels 10 can be suppressed. Even in a case where the first substrate section FB is stacked on the light incidence surface side of the second substrate section SB having the SPAD pixels 10, light can be caused to enter the SPAD pixels 10 efficiently. Thus, deterioration of characteristics the SPAD pixels 10 (e.g., conversion efficiency (QE)) can be suppressed.

In addition, the second substrate section SB further has the separation region 508 that is provided in the second semiconductor substrate 6 and separates one SPAD pixel 10 and another SPAD pixel 10 that are adjacent to each other among the plurality of SPAD pixels 10. The first light shading walls 150 are arranged at positions overlapping the separation region 508 in the thickness direction (e.g., the Z-axis direction) of the multilayered substrate 200.

Thus, the combinations of the first light shading walls 150 and the separation region 508 can substantially extend the light shading walls in the thickness direction (e.g., the Z-axis direction) of the multilayered substrate, and color mixing between the SPAD pixels 10 can be suppressed further. For example, deterioration of the conversion efficiency (QE) can be suppressed further.

In addition, the first semiconductor substrate 5 has the waveguide regions 11 that are at positions overlapping the SPAD pixels 10 in the thickness direction (e.g., the Z-axis direction) of the multilayered substrate 200 and are for introducing light having entered the other surface opposite the one surface of the first substrate section FB to the SPAD pixels 10 in the second substrate section SB. The CIS pixels 20 are not arranged in the waveguide regions 11.

Thus, the CIS pixels 20 are not provided on optical paths from the rear surface 5b (light incidence surface) of the first semiconductor substrate 5 to the SPAD pixels 10, and it becomes easier to arrange wires or the like connected to the CIS pixels 20 at positions away from the optical paths. It is possible to prevent the light heading to the SPAD pixels 10 from being attenuated or reflected by hitting the CIS pixels 20 or the wires or the like connected to the CIS pixels 20. Thus, for example, deterioration of the conversion efficiency (QE) can be suppressed further.

In addition, the multilayered substrate 200 has the waveguides LGR that are provided between the waveguide regions 11 and the SPAD pixels 10 and are for introducing the light from the waveguide regions 11 to the SPAD pixels 10. Thus, it is possible to cause the light to propagate efficiently from the waveguide regions 11 to the SPAD pixels 10.

In addition, the multilayered substrate 200 further has the second light shading walls 160 provided between the first light shading walls 150 and the waveguides LGR. Thus, the combinations of the first light shading walls 150 and the second light shading walls 160 can doubly surround the optical paths from the front surface 5a (light exit surface) of the first semiconductor substrate 5 to the SPAD pixels 10 and can doubly surround the waveguides LGR, for example. Thus, color mixing between the SPAD pixels 10 can be suppressed further. For example, deterioration of the conversion efficiency (QE) can be suppressed further.

### Modification Examples of First Embodiment

In the case depicted in the first embodiment described above, for example, as depicted in FIG. 10, the area size of a waveguide region 11 is four times greater than the pixel area size of a CIS pixel 20 (a length corresponding to two pixels in the X-axis direction, and a length corresponding to two pixels in the Y-axis direction). In addition, as depicted in FIG. 7, the arrangement intervals between waveguide regions 11 are four times greater than the arrangement intervals between CIS pixels 20 (i.e., a length corresponding to four CIS pixels 20). However, embodiments of the present disclosure are not limited to these. For example, modes depicted in first to fourth modification examples depicted in the following FIG. 11 to FIG. 14 may be adopted. Even with such a configuration, advantages similar to those of the first embodiment described above can be attained.

### (1) First Modification Example

FIG. 11 is a plan view depicting a size example (first modification example) of the waveguide regions 11 of the light sensing device 100 according to the first embodiment of the present disclosure. In the first modification example depicted in FIG. 11, the area size of a waveguide region 11 is four times greater than the pixel area size of a CIS pixel 20 (a length corresponding to two pixels in the X-axis direction, and a length corresponding to two pixels in the Y-axis direction). The arrangement intervals between waveguide regions 11 are six times greater than the arrangement intervals between CIS pixels 20 (i.e., a length corresponding to six CIS pixels 20).

### (2) Second Modification Example

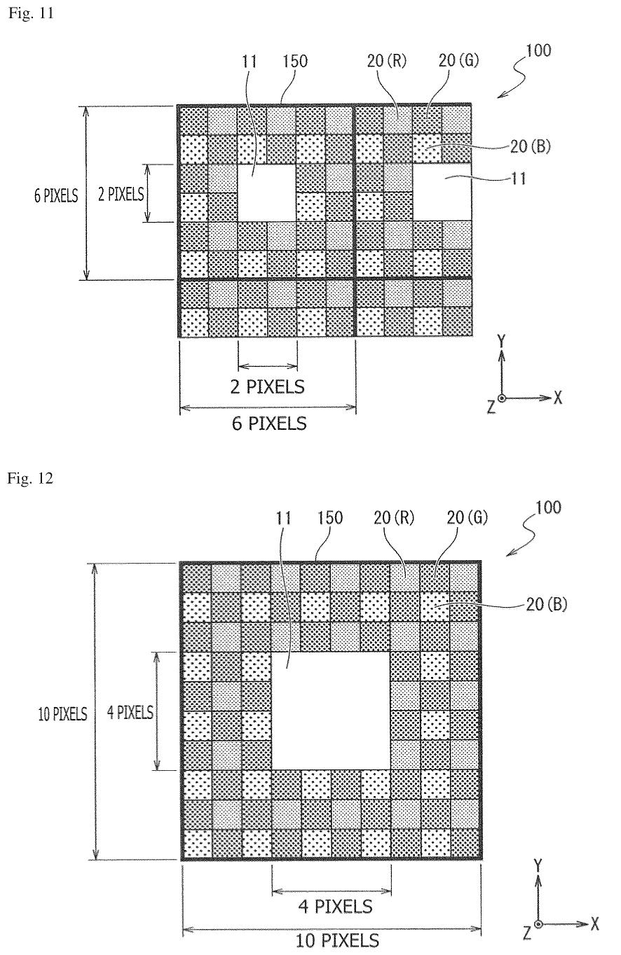

FIG. 12 is a plan view depicting a size example (second modification example) of the waveguide regions 11 of the light sensing device 100 according to the first embodiment of the present disclosure. In the second modification example depicted in FIG. 12, the area size of a waveguide region 11 is sixteen times greater than the pixel area size of a CIS pixel 20 (a length corresponding to four pixels in the X-axis direction, and a length corresponding to four pixels in the Y-axis direction). Although not depicted, for example, the arrangement intervals between waveguide regions 11 are ten times greater than the arrangement intervals between CIS pixels 20 (i.e., a length corresponding to ten CIS pixels 20).

### (3) Third Modification Example

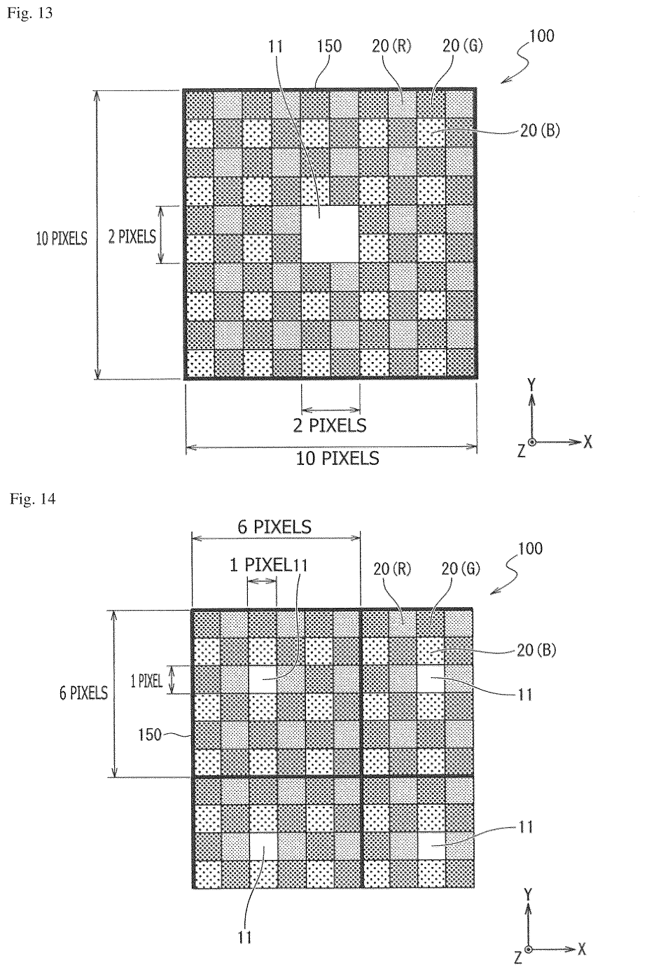

FIG. 13 is a plan view depicting a size example (third modification example) of the waveguide regions 11 of the light sensing device 100 according to the first embodiment of the present disclosure. In the third modification example depicted in FIG. 13, the area size of a waveguide region 11 is four times greater than the pixel area size of a CIS pixel 20 (a length corresponding to two pixels in the X-axis direction, and a length corresponding to two pixels in the Y-axis direction). Although not depicted, for example, the arrangement intervals between waveguide regions 11 are ten times greater than the arrangement intervals between CIS pixels 20 (i.e., a length corresponding to ten CIS pixels 20).

### (4) Fourth Modification Example

FIG. 14 is a plan view depicting a size example (fourth modification example) of the waveguide regions 11 of the light sensing device 100 according to the first embodiment of the present disclosure. In the fourth modification example depicted in FIG. 14, the area size of a waveguide region 11 is equal to the pixel area size of a CIS pixel 20 (a length corresponding to one pixel in the X-axis direction, and a length corresponding to one pixel in the Y-axis direction). Although not depicted, for example, the arrangement intervals between waveguide regions 11 are six times greater than the arrangement intervals between CIS pixels 20 (i.e., a length corresponding to six CIS pixels 20).

### Second Embodiment

In the first embodiment described above, the second light shading walls 160 arranged between the first light shading walls 150 and the waveguides LGR are explained as including the first wires 551, the first connection pads 552, and the second connection pads 652. However, embodiments of the present disclosure are not limited to this. For example, the second light shading walls 160 may include only the first wires 551 or may include the first wires 551 and the first connection pads 552.

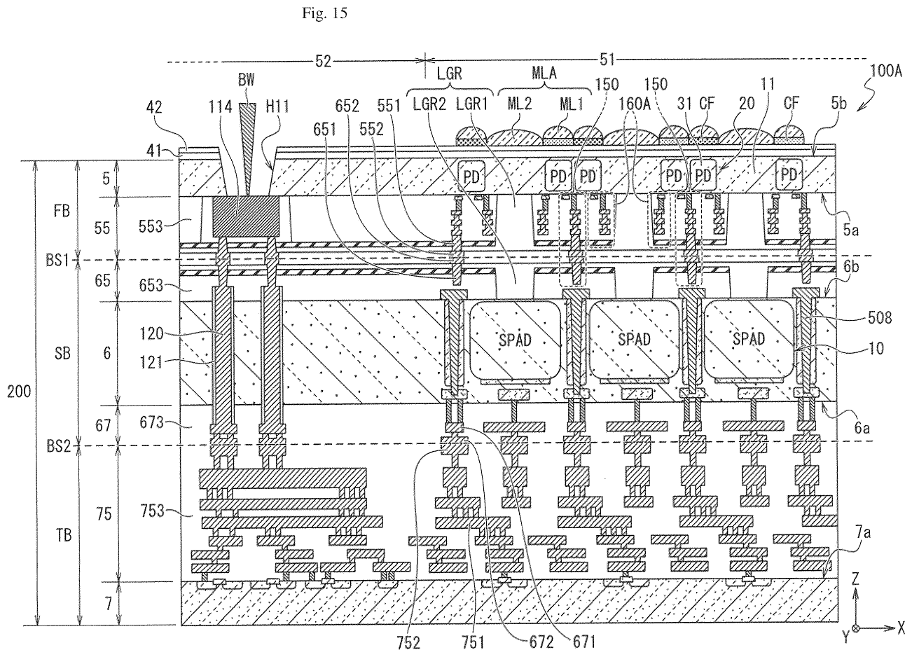

FIG. 15 is a cross-sectional view depicting a configuration example of a light sensing device 100A according to a second embodiment of the present disclosure. As depicted in FIG. 15, the light sensing device 100A has second light shading walls 160A. The second light shading walls 160A include only the first wires 551 in the first wiring layer 55. The second light shading walls 160A do not include the first connection pads 552 and the second connection pads 652.

The second light shading walls 160A are arranged between the first light shading walls 150 and the waveguides LGR. The second light shading walls 160A are arranged to surround the waveguides LGR continuously in plan view as seen in the Z-axis direction. The second light shading walls 160A are arranged to surround individual ones of the multiple waveguide regions 11.

Even with such a configuration, in the light sensing device 100A, the combinations of the first light shading walls 150 and the second light shading walls 160 can doubly surround the optical paths from the front surface 5a (light exit surface) of the first semiconductor substrate 5 to the SPAD pixels 10 and can doubly surround the waveguides LGR, for example. Thus, color mixing between the SPAD pixels 10 can be suppressed further. As in the light sensing device 100 according to the first embodiment, for example, deterioration of the conversion efficiency (QE) can be suppressed further.

### Third Embodiment

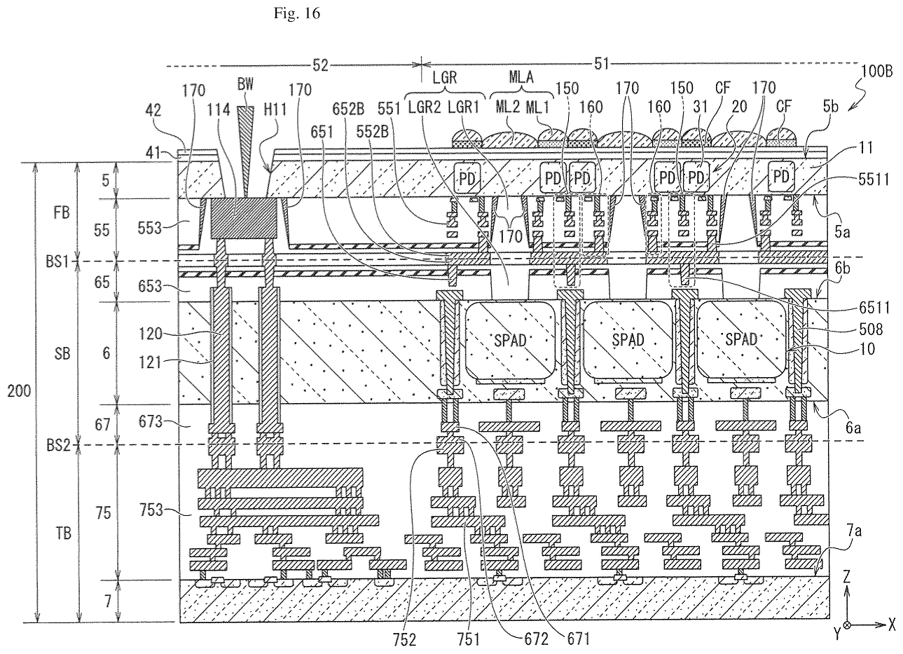

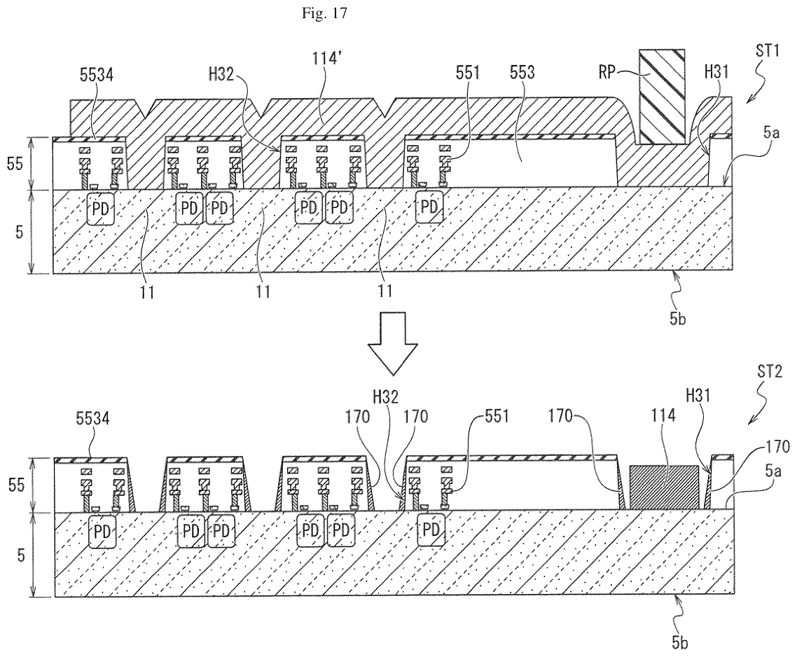

In embodiments of the present disclosure, third light shading walls may be provided between the second light shading walls and the waveguides. FIG. 16 is a cross-sectional view depicting a configuration example of a light sensing device 100B according to a third embodiment of the present disclosure. As depicted in FIG. 16, the light sensing device 100B has light shading sidewalls 170 (an example of “third light shading walls” of an embodiment of the present disclosure) between the second light shading walls 160 and the waveguides LGR. For example, the light shading sidewalls 170 are provided along the outer circumference sides of the waveguides LGR. For example, the light shading sidewalls 170 include aluminum (Al) or an Al alloy. The light shading sidewalls 170 can be formed incidentally when the bonding pads 114 are formed by dry etching. This is explained with reference to FIG. 17.

FIG. 17 is a step diagram depicting a method of forming the bonding pads 114 and the light shading sidewalls 170 which is a part of steps to manufacture the light sensing device 100B according to the third embodiment of the present disclosure. Note that the light sensing device is manufactured by use of various types of devices such as film forming devices (including a CVD (Chemical Vapor Deposition) device, a sputtering device, and a thermal oxidation device), a light-exposure device, a dry etching device, a wet etching device, or a CMP device. Hereinbelow, these devices are collectively referred to as a manufacturing device.

At Step ST1 in FIG. 17, the first interlayer dielectric film 553 including the SiN film 5534 is provided on the front surface 5a side of the first semiconductor substrate 5. The first interlayer dielectric film 553 is provided with an opening H31 as an opening of a region where a bonding pad 114 is to be provided and regions around and above the region, and openings H32 as openings above the waveguide regions 11. In addition, a metal film 114′ is provided on the SiN film 5534 in the first interlayer dielectric film 553. The metal film 114′ fills the openings H31 and H32.

At Step ST1 in FIG. 17, the manufacturing device forms a resist pattern RP on the metal film 114′. The resist pattern RP has a shape that covers, from above, the region where the bonding pad 114 (see FIG. 16) is to be formed and has an opening above the other regions. Next, the manufacturing device dry-etches the metal film 114′ with the resist pattern RP used as a mask. Thus, as depicted as Step ST2 in FIG. 17, the bonding pad 114 and the light shading sidewalls 170 are formed from the metal film 114′. The light shading sidewalls 170 are formed at the side surface of the opening H31 where the bonding pad 114 is positioned and the side surfaces of the openings H32 positioned above the waveguide regions 11. Thereafter, the manufacturing device removes the resist pattern RP. The light shading sidewalls 170 are formed by such a manufacturing method.

Note that, for example, the openings H31 and H32 are filled with the HDP film 5535 (see FIG. 8) provided on the front surface 5a side of the first semiconductor substrate 5. The HDP film 5535 is a dielectric film to form the first waveguides LGR1 depicted in FIG. 16. In addition, the pad opening section H11 depicted in FIG. 16 is formed by etching the rear surface 5b side of the first semiconductor substrate 5 at an optional step after the openings H31 and H32 are filled with the HDP film 5535.

In the light sensing device 100B depicted in FIG. 16, the outer circumference sides of the first waveguides LGR1 are covered with the light shading sidewalls 170. Thus, the combinations of the first light shading walls 150, the second light shading walls 160, and the light shading sidewalls 170 can triply surround the waveguides LGR. Thus, color mixing between the SPAD pixels 10 can be suppressed further, and, for example, deterioration of the conversion efficiency (QE) can be suppressed further.

In addition, as depicted in FIG. 16, the first wiring layer 55 of the light sensing device 100B has first connection pads 552B which are a modification example of the first connection pads 552 (see FIG. 7). The second wiring layer 65 has second connection pads 652B which are a modification example of the second connection pads 652 (see FIG. 7). The first connection pads 552B and the second connection pads 652B both include copper (Cu) or a Cu alloy and are Cu-Cu-bonded together. The first connection pads 552B and the second connection pads 652B are arranged between the CIS pixels 20 and the second semiconductor substrate 6.

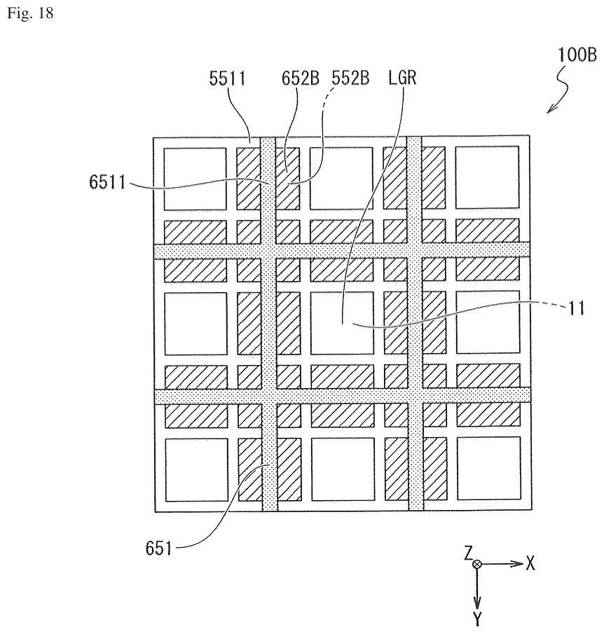

FIG. 18 is a plan view illustrating a positional relation between the first connection pads 552B and the second connection pads 652B, and the waveguide regions 11 and the CIS pixels 20 in the light sensing device 100B according to the third embodiment of the present disclosure. FIG. 18 is a diagram depicting the first connection pads 552B and the second connection pads 652B as seen from the side where the second substrate section SB is.

As depicted in FIG. 16, the first connection pads 552B and the second connection pads 652B are arranged below the CIS pixels 20. As depicted in FIG. 18, in plan view as seen in the thickness direction (e.g., the Z-axis direction) of the multilayered substrate 200, the CIS pixels 20 are arranged at positions overlapping the first connection pads 552B and the second connection pads 652B.

Thus, the first connection pads 552B and the second connection pads 652B function as light shading walls to shade the CIS pixels 20 from light from the SPAD pixels 10. The first connection pads 552B and the second connection pads 652B can prevent light reflected from the SPAD pixels 10 or light generated by avalanche emission in the SPAD pixels 10 from entering the CIS pixels 20. Thus, for example, it is possible to reduce noise generated to the CIS pixels 20 caused by light from the SPAD pixels 10.

In addition, the first wires 551 in the first wiring layer 55 may be connected to the first connection pads 552B. For example, as depicted in FIG. 16 and FIG. 18, wires 5511 included in the second light shading walls 160 in the first wires 551 may be connected to the first connection pads 552B. The wires 5511 are connected to the outer circumferential portions of the first connection pads 552B. Thus, it becomes possible to block, with the wires 5511, reflected light or light generated by avalanche emission from the SPAD pixels 10, and this contributes to enhancement of the light-shading property and color mixing prevention. Note that the wires 5511 may be signal lines or may be electrically-floating dummy wires.

Similarly, the second wires 651 in the second wiring layer 65 may be connected to the second connection pads 652B. For example, as depicted in FIG. 16 and FIG. 18, wires 6511 included in the first light shading walls 150 in the second wires 651 may be connected to the second connection pads 652B. The wires 6511 are positioned above the separation region 508. Thus, it becomes possible to block, with the wires 6511, entrance of light from one SPAD pixel 10 to another SPAD pixel 10 adjacent to the one SPAD pixel 10, and the light-shading property between adjacent SPAD pixels 10 can be enhanced. Note that the wires 6511 may be signal lines or may be electrically-floating dummy wires. In addition, as depicted in FIG. 16, the wires 6511 and the separation region 508 may be insulated by the second interlayer dielectric films 653.

### Fourth Embodiment

In an embodiment of the present disclosure, the waveguide regions 11 in the first semiconductor substrate 5 may be provided with through holes penetrating the first semiconductor substrate 5 in the thickness direction (e.g., the Z-axis direction). In addition, the through holes may be provided with waveguides by being filled with a light-transmitting member.

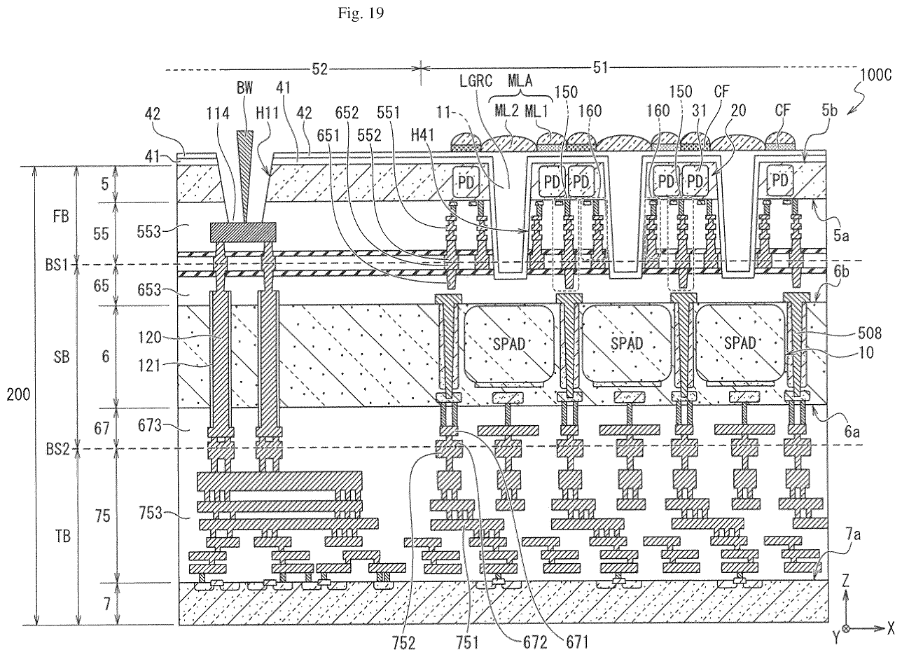

FIG. 19 is a cross-sectional view depicting a configuration example of a light sensing device 100C according to a fourth embodiment of the present disclosure. As depicted in FIG. 19, in the light sensing device 100C, the first substrate section FB including the first semiconductor substrate 5 and the first wiring layer 55 is provided with through holes H41 penetrating the first substrate section FB in the thickness direction (e.g., the Z-axis direction). The through holes H41 are provided in the waveguide regions 11 in the first semiconductor substrate 5.

The bottom planes and side surfaces of the through holes H41 are covered with the light-transmitting dielectric film 41. In addition, the through holes H41 are filled with the light-transmitting dielectric film 42 via the dielectric film 41. The dielectric film 42 filling the through holes H41 forms waveguides LGRC to the SPAD pixels 10. Thus, the waveguides LGRC penetrate the waveguide regions 11 in the first semiconductor substrate 5 in the Z-axis direction.

For example, the dielectric film 41 is silicon nitride (SiN), and the dielectric film 42 is a silicon oxide (SiO) film. The refractive index of the dielectric film 41 is higher than the refractive index of the dielectric film 42. Thus, it is possible to prevent light having entered the waveguides LGRC from being reflected at the interface between the dielectric film 41 and the dielectric film 42 included in the waveguides LGRC. In addition, due to the difference between the refractive indices described above, it is possible to suppress entrance of reflected light from the SPAD pixels 10 or light generated by avalanche emission in the SPAD pixels 10 into the waveguides.

In addition, as in the light sensing device 100 according to the first embodiment, the dielectric films 41 and 42 are used as protective films to protect the rear surface 5b of the first semiconductor substrate 5. Since, instead of forming dielectric films to be used solely as waveguides for forming the waveguides LGRC, the dielectric films 41 and 42 can be used also as waveguides, an increase of the number of manufacturing steps can be suppressed.

Methods for forming the dielectric films 42 included in the waveguides LGRC are not limited particularly to any kind, and a spin on glass (SOG) method can be used, for example. For example, in the SOG method, siloxane is discharged onto the rear surface 5b of a wafer (i.e., the first semiconductor substrate 5 before dicing) having openings H41 formed therethrough and the dielectric film 41 formed thereon, the wafer is rotated fast, and siloxane is caused to spread by centrifugal force to form a thin film. By performing thermal treatment on this thin film, an SiO film including siloxane as a raw material can be formed. The SOG method excels in its capability to fill the openings and attain flatness and can form the waveguides LGRC relatively easily.

### Fifth Embodiment

The waveguide regions are arranged above the SPAD pixels 10 (i.e., on the light incidence surface side) in the modes depicted in the first to fourth embodiments described above. However, embodiments of the present disclosure are not limited to this.

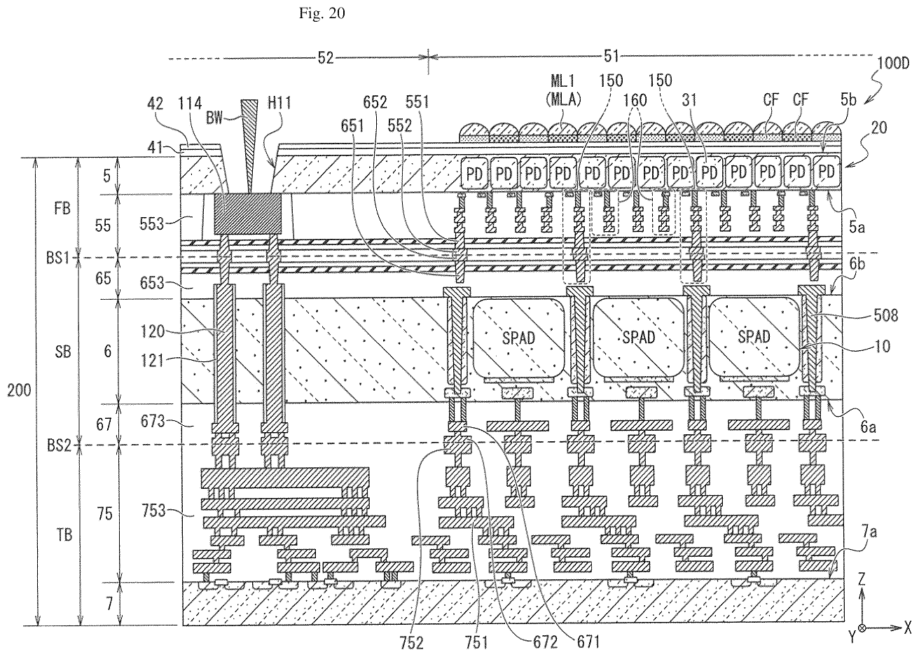

FIG. 20 is a cross-sectional view depicting a configuration example of a light sensing device 100D according to a fifth embodiment of the present disclosure. As depicted in FIG. 20, waveguide regions 11 (see FIG. 7) are not arranged above the SPAD pixels 10 in the light sensing device 100D. Instead of waveguide regions 11, the CIS pixels 20 are arranged above the SPAD pixels 10.

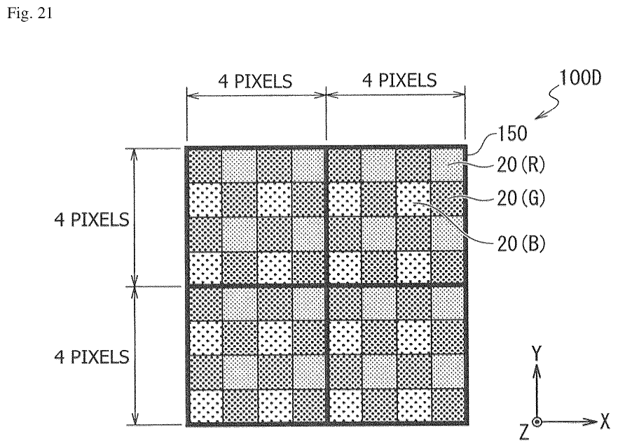

FIG. 21 is a plan view illustrating a positional relation between the first light shading walls 150 and the CIS pixels 20 in the light sensing device 100D according to the fifth embodiment of the present disclosure. In FIG. 21, a CIS pixel 20(R) represents a CIS pixel positioned under a red color filter CF (see FIG. 20), a CIS pixel 20(G) represents a CIS pixel positioned under a green color filter CF, and a CIS pixel 20(B) represents a CIS pixel positioned under a blue color filter CF.

As depicted in FIG. 21, the light sensing device 100D does not have waveguide regions 11. The area size of an SPAD pixel 10 (see FIG. 20) positioned under a CIS pixel 20 is not limited particularly to any size, and is sixteen times greater than the pixel area size of the CIS pixel 20 (a length corresponding to four pixels in the X-axis direction, and a length corresponding to four pixels in the Y-axis direction) in the example depicted in FIG. 21. In this case, the arranged intervals between the SPAD pixels 10 are four times greater than the arrangement intervals between CIS pixels 20 (i.e., a length corresponding to four CIS pixels 20).

As depicted in FIG. 21, the first light shading walls 150 are arranged to surround individual ones of the plurality of SPAD pixels 10 continuously in a plan view as seen in the thickness direction (e.g., the Z-axis direction) of the multilayered substrate 200.

According to the light sensing device 100D according to the fifth embodiment, light transmitted not through the waveguide regions 11 but through the CIS pixels 20 enters the SPAD pixels 10 positioned below the CIS pixels 20. The light sensing device 100D has the separation region 508 that separates adjacent SPAD pixels 10 and has the first light shading walls 150 in the separation region 508. Since the first light shading walls 150 can surround, for each SPAD pixel 10, a path of light that is transmitted through a CIS pixel 20 and enters the SPAD pixel 10, color mixing between SPAD pixels 10 can be suppressed. For example, deterioration of the conversion efficiency (QE) can be suppressed.

In addition, the light sensing device 100D has the second light shading walls 160 in addition to the first light shading walls 150. For example, the second light shading walls 160 include only the first wires 551 in the first wiring layer 55. Since the combinations of the first light shading walls 150 and the second light shading walls 160 can doubly surround the optical paths from the front surface 5a (light exit surface) of the first semiconductor substrate 5 to the SPAD pixels 10 in the light sensing device 100D, color mixing between the SPAD pixels 10 and color mixing between the CIS pixels 20 due to reflected light or the like are likely to be suppressed further.

Note that, as in other embodiments, the second light shading walls 160 may not be present also in the fifth embodiment. In the light sensing device 100D, the second light shading walls 160 are not essential constituent elements, and the second light shading walls 160 are not present in other possible configurations.

### Examples of Application to Mobile Bodies

The technology according to the present disclosure (present technology) can be applied to various products. For example, the technology according to the present disclosure may be realized as a device to be mounted on any type of mobile body such as an automobile, an electric automobile, a hybrid electric automobile, a motorcycle, a bicycle, a personal mobility, an airplane, a drone, a ship, or a robot.

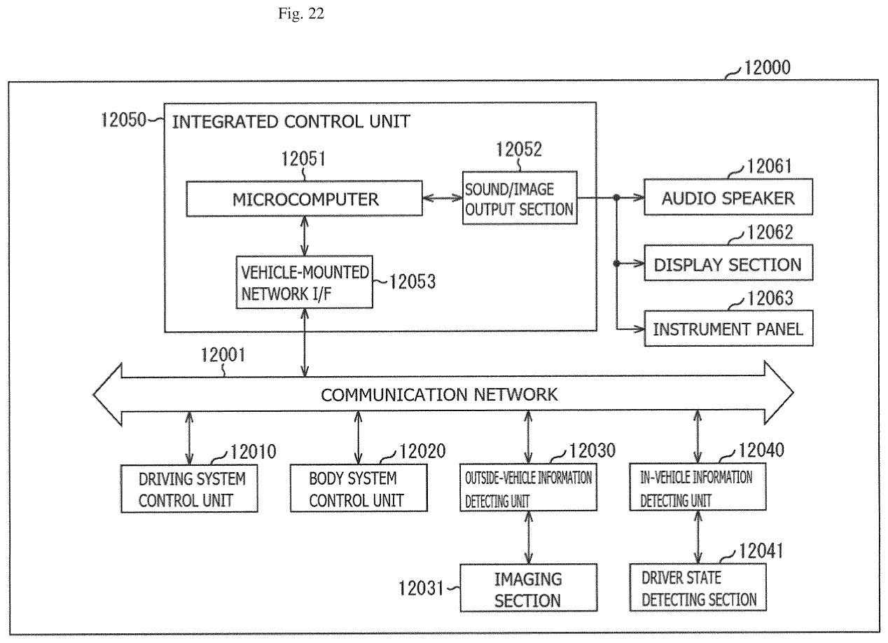

FIG. 22 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 22, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 22, an audio speaker 12061, a display section 12062, and an instrument panel 12063 are illustrated as the output device. The display section 12062 may, for example, include at least one of an on-board display and a head-up display.

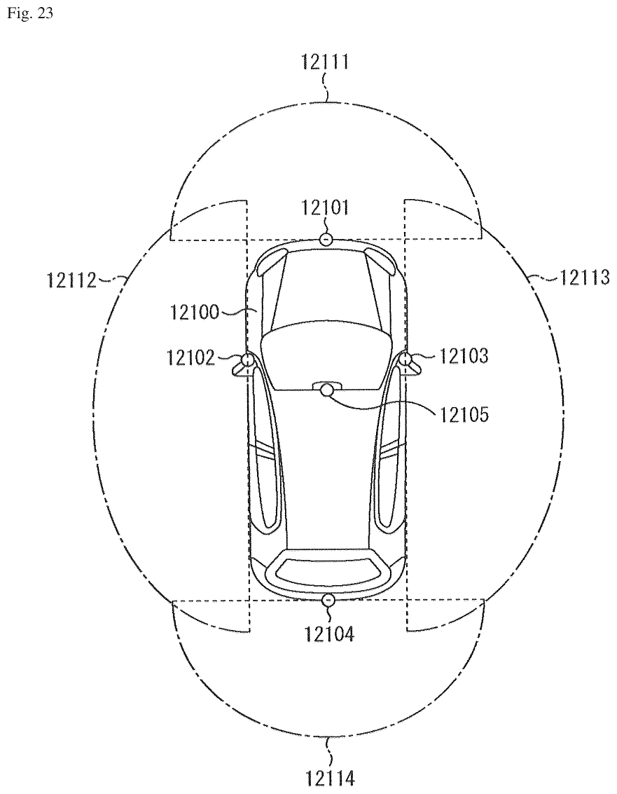

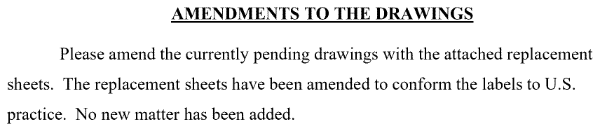

FIG. 23 is a diagram depicting an example of the installation position of the imaging section 12031.

In FIG. 23, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 23 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to an embodiment of the present disclosure can be applied has been explained thus far. The technology according to an embodiment of the present disclosure can be applied to the imaging section 12031 or the like in the configuration explained above. Specifically, the light sensing devices 100 and 100A to 100D can be applied to the imaging section 12031. By applying the technology according to an embodiment of the present disclosure to the imaging section 12031, it is possible to cause light to enter the SPAD pixels 10 efficiently in an imaging device included in the imaging section 12031, and, for example, deterioration of the conversion efficiency (QE) can be suppressed.

### Other Embodiments

Whereas, as described above, the present disclosure has been described with use of embodiments, modification examples, and application examples, statements and figures forming a part of this disclosure should not be understood as limiting the present disclosure. Various alternative embodiments, implementation examples, and operational technologies will be apparent to those skilled in the art from this disclosure.

For example, the light sensing devices 100 and 100A to 100D according to the first to fifth embodiments described above may have configuration having not both the first light shading walls 150 and the second light shading walls 160, but only either of them. The light sensing devices 100 and 100A to 100C may have a configuration that has the waveguide regions 11 and the waveguides LGR in which CIS pixels are not arranged in the first semiconductor substrate 5 and is not provided with the first light shading walls 150 and the second light shading walls 160. The light shading sidewalls 170 of the light sensing device 100B may be applied to the light sensing devices 100, 100A, 100C, and 100D. The configuration of the first connection pads 552B and second connection pads 652B of the light sensing device 100B also may be applied to the light sensing devices 100, 100A, 100C, and 100D.

In such a manner, certainly, the present technology includes various embodiments and the like not described here. Within the scope not departing from the gist of the embodiments and modification examples mentioned above, at least one of various types of omission, replacement, and modification of constituent elements can be performed. In addition, advantages described in the present specification are merely illustrated as examples, advantages of the present disclosure are not limited to them, and there may be other advantages.

Note that the present disclosure can also take the following configurations.
(1)

A light sensing device including:
a multilayered substrate having a first substrate section and a second substrate section bonded to one surface of the first substrate section, in which
the first substrate section has
a first semiconductor substrate, and
a plurality of imaging pixels provided in the first semiconductor substrate,
the second substrate section has
a second semiconductor substrate that faces the first semiconductor substrate, and
a plurality of distance measurement pixels provided in the second semiconductor substrate, and
the multilayered substrate further has first light shading walls that are provided between the first semiconductor substrate and the second semiconductor substrate and surround individual ones of the distance measurement pixels in a plan view as seen in a thickness direction of the multilayered substrate.
(2)

The light sensing device according to (1) above, in which
the second substrate section further has a separation region that is provided in the second semiconductor substrate and separates one distance measurement pixel and another distance measurement pixel that are adjacent to each other, among the plurality of distance measurement pixels, and
the first light shading walls are arranged at positions overlapping the separation region in the thickness direction.
(3)

The light sensing device according to one or more of (1) and (2) above, in which the first light shading walls surround the distance measurement pixels uninterruptedly and continuously in the plan view as seen in the thickness direction.
(4)

The light sensing device according to any one or more of (1) to (3) above, in which the first light shading walls have
first parts that are provided in the first substrate section and face the second substrate section, and
second parts that are provided in the second substrate section and face the first substrate section.
(5)

The light sensing device according to any one or more of (1) to (4) above, in which the first substrate section has a first wiring layer provided on a surface side of the first semiconductor substrate that faces the second semiconductor substrate,
the second substrate section has a second wiring layer provided on a surface side of the second semiconductor substrate that faces the first semiconductor substrate,
the first wiring layer has a first interlayer dielectric film and first wires,
the second wiring layer has a second interlayer dielectric film and second wires,
the first parts include the first wires, and
the second parts include the second wires.
(6)

The light sensing device according to any one or more of (1) to (5) above, in which
the first wiring layer has first connection pads including copper (Cu) or a Cu alloy,
the second wiring layer has second connection pads including Cu or a Cu alloy,
the first connection pads and the second connection pads are Cu-Cu-bonded together at a bonding portion between the first substrate section and the second substrate section,
the first parts include first connection pads, and
the second parts include second connection pads.
(7)

The light sensing device according to any one or more of (1) to (6) above, in which the first connection pads included in the first parts and the second connection pads included in the second parts are arranged between the imaging pixels and the second semiconductor substrate.
(8)

The light sensing device according to any one or more of (1) to (7) above, in which
the first semiconductor substrate has waveguide regions that are at positions overlapping the distance measurement pixels in the thickness direction and are for introducing light having entered the other surface opposite the one surface of the first substrate section to the distance measurement pixels in the second substrate section, and
the imaging pixels are not arranged in the waveguide regions.
(9)

The light sensing device according to any one or more of (1) to (8) above, in which the waveguide regions are adjacent to the imaging pixels.
(10)

The light sensing device according to any one or more of (1) to (9) above, in which the multilayered substrate has waveguides that are provided between the waveguide regions and the distance measurement pixels and are for introducing the light from the waveguide regions to the distance measurement pixels.
(11)

The light sensing device according to any one or more of (1) to (10) above, in which the waveguides include only silicon oxide.
(12)

The light sensing device according to any one or more of (1) to (11) above, in which the waveguides penetrate the waveguide regions in the thickness direction.
(13)

The light sensing device according to any one or more of (1) to (12) above, in which the multilayered substrate further has second light shading walls provided between the first light shading walls and the waveguides.
(14)

The light sensing device according to any one or more of (1) to (13) above, in which the multilayered substrate further has third light shading walls provided on side surfaces of the waveguides.
(15)

The light sensing device according to any one or more of (1) to (14) above, in which
the multilayered substrate further includes a third substrate section arranged opposite the first substrate section with the second substrate section being interposed therebetween, and
the third substrate section has
a third semiconductor substrate, and
an electronic circuit provided in the third semiconductor substrate.
(16)

The light sensing device according to any one or more of (1) to (15) above, in which the electronic circuit includes at least either of distance-measurement pixel circuits connected to the distance measurement pixels and imaging pixel circuits connected to the imaging pixels.
(17)

The light sensing device according to any one or more of (1) to (16) above, further including:
lens bodies arranged opposite the second substrate section with the first substrate section being interposed therebetween, in which
the lens bodies have
first lenses that condense light onto the imaging pixels, and
second lenses that condense light onto the distance measurement pixels, and
the first lenses and the second lenses have mutually different curvatures.
(18)

The light sensing device according to any one or more of (1) to (17) above, in which the distance measurement pixels are single photon avalanche diode pixels.
(19)

A light sensing device including:
a multilayered substrate having a first substrate section and a second substrate section bonded to one surface of the first substrate section, in which
the first substrate section has
a first semiconductor substrate, and
a plurality of imaging pixels provided in the first semiconductor substrate,
the second substrate section has
a second semiconductor substrate that faces the first semiconductor substrate, and
a plurality of distance measurement pixels provided in the second semiconductor substrate, and
the first semiconductor substrate has waveguide regions that are at positions overlapping the distance measurement pixels in a thickness direction of the multilayered substrate and are for introducing light having entered the other surface opposite the one surface of the first substrate section to the distance measurement pixels in the second substrate section,
the imaging pixels are not arranged in the waveguide regions, and
the multilayered substrate has waveguides that are provided between the waveguide regions in the first semiconductor substrate and the distance measurement pixels in the second semiconductor substrate and are for introducing the light from the waveguide regions to the distance measurement pixels.
(20) A light detecting device comprising:
a first substrate section including:
a first semiconductor substrate; and
a plurality of photodiodes in the first semiconductor substrate;
a second substrate section stacked on the first substrate section including:
a second semiconductor substrate; and
a plurality of avalanche photodiodes in the second semiconductor substrate; and
first light shielding walls disposed in the first substrate section and the second substrate section,
wherein a part of the first light shielding walls surround a region in a cross-sectional view, the region disposed above the first avalanche photodiode of the plurality of avalanche photodiodes in a light-receiving direction.
(21) The light detecting device according to (20), wherein
the second substrate section further includes a separation region disposed in the second semiconductor substrate, wherein the separation region separates a first avalanche photodiode from a second avalanche photodiode adjacent to the first avalanche photodiode, and
the first light shielding walls are disposed above the separation region in a light-receiving direction.
(22) The light detecting device according to (20) and/or (21), wherein each of the plurality of the first light shielding walls surrounding the region is connected to another of the plurality of the first light shielding walls.
(23) The light detecting device according to any one or more of (20) to (22), wherein
the first light shielding walls have first parts disposed in the first substrate section and
second parts of the first light shielding walls disposed in the second substrate section.
(24) The light detecting device according to any one or more of (20) to (23), wherein
the first substrate section further includes a first wiring layer disposed on a surface side of the first semiconductor substrate, wherein the first wiring layer faces the second semiconductor substrate,
the second substrate section further includes a second wiring layer disposed on a surface side of the second semiconductor substrate, wherein the second wiring layer faces the first semiconductor substrate,
the first wiring layer comprises a first interlayer dielectric film and first wires,
the second wiring layer comprises a second interlayer dielectric film and second wires,
the first parts of the first light shielding walls include the first wires, and
the second parts of the first light shielding walls include the second wires.
(25) The light detecting device according to any one or more of (20) to (24), wherein
the first wiring layer comprises first connection pads including one or more of copper (Cu) and a Cu alloy,
the second wiring layer comprises second connection pads including one or more of Cu and a Cu alloy,
the first connection pads and the second connection pads are bonded together at a bonding portion between the first substrate section and the second substrate section,
the first parts of the first light shielding walls include the first connection pads, and
the second parts of the first light shielding walls include the second connection pads.
(26) The light detecting device according to any one or more of (20) to (25), wherein
the first connection pads included in the first parts of the first light shielding walls and
the second connection pads included in the second parts of the first light shielding walls are arranged between the first semiconductor substrate and the second semiconductor substrate.
(27) The light detecting device according to any one or more of (20) to (26), wherein
the region is a waveguide region, and
the first avalanche photodiode is not arranged in the waveguide region.
(28) The light detecting device according to any one or more of (20) to (27), wherein
the first substrate section comprises the waveguide region.
(29) The light detecting device according to any one or more of (20) to (28), further comprising a second light shielding wall between the first light shielding walls and the waveguide region.
(30) The light detecting device according to any one or more of (20) to (29), further comprising a second waveguide in the second substrate section.
(31) The light detecting device according to any one or more of (20) to (30), wherein the waveguide region is surrounded by the first light shielding walls in the cross-sectional view.
(32) The light detecting device according to any one or more of (20) to (31), wherein a through hole penetrates the first substrate section in the waveguide region.
(33) The light detecting device according to any one or more of (20) to (32), wherein the waveguide region comprises silicon oxide (SiO).
(34) The light detecting device according to any one or more of (20) to (33), wherein
the light detecting device further includes a third substrate section, and
the third substrate section includes:
a third semiconductor substrate, and
processing circuitry provided in the third semiconductor substrate.
(35) The light detecting device according to any one or more of (20) to (34), wherein the processing circuitry includes at least either of avalanche photodiode circuits connected to the avalanche photodiodes and imaging pixel circuits connected to the photodiodes.
(36) The light detecting device according to any one or more of (20) to (35), further comprising lens bodies arranged opposite the second substrate section with the first substrate section being interposed therebetween, wherein the lens bodies include:
first lenses that condense light onto the photodiodes, and
second lenses that condense light onto the avalanche photodiodes, and wherein the first lenses and the second lenses have mutually different curvatures.
(37) The light detecting device according to any one or more of (20) to (36), wherein the avalanche photodiodes are single photon avalanche diode pixels.
(38) A light detecting apparatus comprising:
a plurality of lenses;
a first substrate section including:
a first semiconductor substrate; and
a plurality of photodiodes in the first semiconductor substrate;
a second substrate section stacked on the first substrate section including:
a second semiconductor substrate; and
a plurality of avalanche photodiodes in the second semiconductor substrate; and
first light shielding walls disposed in the first substrate section and the second substrate section,
wherein a plurality of the first light shielding walls surround a waveguide region in a cross-sectional view.
(39) The light detecting device according to (38), wherein
the second substrate section further includes a separation region disposed in the second semiconductor substrate, wherein the separation region separates a first avalanche photodiode from a second avalanche photodiode adjacent to the first avalanche photodiode, and
the first light shielding walls are disposed above the separation region in a light-receiving direction.

### REFERENCE SIGNS LIST

1: Imaging section
2: Distance measuring section
5: First semiconductor substrate
5a, 6a, 7a: Front surface
5b, 6b: Rear surface
6: Second semiconductor substrate
7: Third semiconductor substrate
7a: Front surface
10: SPAD pixel
11: Waveguide region
13: Vertical drive circuit
14: Column signal processing circuit
15: Horizontal drive circuit
16: Output circuit
17: Control circuit
20: CIS pixel
22: Horizontal signal line
23: Vertical signal line
24: Data output signal line
30: Readout circuit
31: PN photodiode
32: Transfer transistor
33: Floating diffusion
34: Amplification transistor
35: Selection transistor
36: Reset transistor
41, 42, 121, 5082: Dielectric film
51: Pixel region
52: Peripheral region
55: First wiring layer
61: First circuit region
62: Second circuit region
65: Second wiring layer
67: Third wiring layer
71: Third circuit region
75: Fourth wiring layer
100, 100A, 100B, 100C, 100D: Light sensing device
101: Distance-measurement processing section
102: Pixel control section
103: Overall control section
104: Clock generating section
106: Interface (I/F)
110: Converting section
111: Generating section
112: Signal processing section
114: Bonding pad
114′: Metal film
120: Conductor
150: First light shading wall
160: Second light shading wall
160A: Second light shading wall
170: Light shading sidewall
200: Multilayered substrate
210: SPAD circuit
211: AFE circuit
212: TDC circuit
213: Histogram circuit
214: Output section
220: CIS circuit
411: Hole accumulation region
501: N-type semiconductor region
502: P-type semiconductor region
503: Well layer
504, 506: Contact
505: Anode
508: Separation region
551: First wire
552, 552B: First connection pad
553: First interlayer dielectric film
651: Second wire
652, 652B: Second connection pad
653: Second interlayer dielectric film
671: Third wire
672: Third connection pad
673: Third interlayer dielectric film
751: Fourth wire
752: Fourth connection pad
753: Fourth interlayer dielectric film
5081: Light-shading film
5511, 6511: Wire
5531, 6531: SiO film
5532: SiC film
5533, 6535: TEOS film
5534, 6533: SiN film
5535, 6534: HDP film
5536, 6532: TEOS film
12000: Vehicle control system
12001: Communication network
12010: Driving system control unit
12020: Body system control unit
12030: Outside-vehicle information detecting unit
12031: Imaging section
12040: In-vehicle information detecting unit
12041: Driver state detecting section
12050: Integrated control unit
12051: Microcomputer
12052: Sound/image output section
12061: Audio speaker
12062: Display section
12063: Instrument panel
12100: Vehicle
12101, 12102, 12103, 12104, 12105: Imaging section
12111, 12112, 12113, 12114: Imaging range
BS1, BS2: Bonding surface
BW: Bonding wire
CF: Color filter
FB: First substrate section
H1, H2, H31, H32, H41: Opening
H11: Pad opening section
H21: Trench
H41: Through hole
I: In-vehicle network
I: Clock generating section
LGR, LGRC, LGRD: Waveguide
LGR 1: First waveguide
LGR 2: Second waveguide
ML1, ML2: Microlens
MLA: Microlens array
RP: Resist pattern
SB: Second substrate section
TB: Third substrate section

What is claimed is:

1. A light detecting device, comprising:
a first substrate section including:
a first semiconductor substrate; and
a plurality of photodiodes in the first semiconductor substrate;
a second substrate section stacked on the first substrate section including:
a second semiconductor substrate; and
a plurality of avalanche photodiodes in the second semiconductor substrate; and
first light shielding walls disposed in the first substrate section and the second substrate section,
wherein a part of the first light shielding walls surround a region in a cross-sectional view, the region disposed above the first avalanche photodiode of the plurality of avalanche photodiodes in a light-receiving direction.

2. The light detecting device according to claim 1, wherein
the second substrate section further includes a separation region disposed in the second semiconductor substrate, wherein the separation region separates a first avalanche photodiode from a second avalanche photodiode adjacent to the first avalanche photodiode, and
the first light shielding walls are disposed above the separation region in a light-receiving direction.

3. The light detecting device according to claim 1, wherein each of the plurality of the first light shielding walls surrounding the region is connected to another of the plurality of the first light shielding walls.

4. The light detecting device according to claim 1, wherein the first light shielding walls have first parts disposed in the first substrate section and second parts of the first light shielding walls disposed in the second substrate section.

5. The light detecting device according to claim 4, wherein
the first substrate section further includes a first wiring layer disposed on a surface side of the first semiconductor substrate, wherein the first wiring layer faces the second semiconductor substrate,
the second substrate section further includes a second wiring layer disposed on a surface side of the second semiconductor substrate, wherein the second wiring layer faces the first semiconductor substrate,
the first wiring layer comprises a first interlayer dielectric film and first wires,
the second wiring layer comprises a second interlayer dielectric film and second wires,
the first parts of the first light shielding walls include the first wires, and
the second parts of the first light shielding walls include the second wires.

6. The light detecting device according to claim 5, wherein
the first wiring layer comprises first connection pads including one or more of copper (Cu) and a Cu alloy,
the second wiring layer comprises second connection pads including one or more of Cu and a Cu alloy,
the first connection pads and the second connection pads are bonded together at a bonding portion between the first substrate section and the second substrate section,
the first parts of the first light shielding walls include the first connection pads, and
the second parts of the first light shielding walls include the second connection pads.

7. The light detecting device according to claim 6, wherein the first connection pads included in the first parts of the first light shielding walls and the second connection pads included in the second parts of the first light shielding walls are arranged between the first semiconductor substrate and the second semiconductor substrate.

8. The light detecting device according to claim 1, wherein
the region is a waveguide region, and
the first avalanche photodiode is not arranged in the waveguide region.

9. The light detecting device according to claim 8, wherein the first substrate section comprises the waveguide region.

10. The light detecting device according to claim 8, further comprising a second light shielding wall between the first light shielding walls and the waveguide region.

11. The light detecting device according to claim 8, further comprising a second waveguide in the second substrate section.

12. The light detecting device according to claim 8, wherein the waveguide region is surrounded by the first light shielding walls in the cross-sectional view.

13. The light detecting device according to claim 8, wherein a through hole penetrates the first substrate section in the waveguide region.

14. The light detecting device according to claim 10, wherein the waveguide region comprises silicon oxide (SiO).

15. The light detecting device according to claim 1, wherein
the light detecting device further includes a third substrate section, and
the third substrate section includes:
a third semiconductor substrate, and
processing circuitry provided in the third semiconductor substrate.

16. The light detecting device according to claim 15, wherein the processing circuitry includes at least either of avalanche photodiode circuits connected to the avalanche photodiodes and imaging pixel circuits connected to the photodiodes.

17. The light detecting device according to claim 1, further comprising lens bodies arranged opposite the second substrate section with the first substrate section being interposed therebetween, wherein the lens bodies include:
first lenses that condense light onto the photodiodes, and
second lenses that condense light onto the avalanche photodiodes, and wherein the first lenses and the second lenses have mutually different curvatures.

18. The light detecting device according to claim 1, wherein the avalanche photodiodes are single photon avalanche diode pixels.

19. A light detecting apparatus, comprising:
a plurality of lenses;
a first substrate section including:
a first semiconductor substrate; and
a plurality of photodiodes in the first semiconductor substrate;
a second substrate section stacked on the first substrate section including:
a second semiconductor substrate; and
a plurality of avalanche photodiodes in the second semiconductor substrate; and
first light shielding walls disposed in the first substrate section and the second substrate section,
wherein a plurality of the first light shielding walls surround a waveguide region in a cross-sectional view.

20. The light detecting apparatus of claim 19, wherein
the second substrate section further includes a separation region disposed in the second semiconductor substrate, wherein the separation region separates a first avalanche photodiode from a second avalanche photodiode adjacent to the first avalanche photodiode, and
the first light shielding walls are disposed above the separation region in a light-receiving direction.
